(19) United States
(12) Patent Application Publication
(10) Pub. No.: US 2023/0317544 A1
(43) Pub. Date: Oct. 5, 2023

(54) INTEGRATED CIRCUIT PACKAGES HAVING REDUCED Z-HEIGHT AND HEAT PATH

(71) Applicant: Intel Corporation, Santa Clara, CA (US)

(72) Inventors: Jan Proschwitz, Riesa SN (DE); Sonja Koller, Bavaria (DE); Thomas Wagner, Regelsbach (DE); Vishnu Prasad, Munich (DE); Wolfgang Molzer, Ottobrunn (DE)

(73) Assignee: Intel Corporation, Santa Clara, CA (US)

(21) Appl. No.: 17/700,211

(22) Filed: Mar. 21, 2022

(51) Int. Cl. H01L 25/18; H01L 23/498; H01L 23/367

(52) U.S. Cl. CPC H01L 23/367; H01L 23/49816; H01L 23/49827; H01L 23/49833; H01L 23/49838; H01L 25/18; H01L 24/73; H01L 2224/73204

(57) ABSTRACT

Disclosed herein are microelectronic assemblies, as well as related apparatuses and methods. For example, in some embodiments, a microelectronic assembly may include a substrate having a first surface including a cavity and an opposing second surface; a die above the cavity and electrically coupled to the second surface of the substrate; a circuit board attached to the substrate; and a cooling apparatus at least partially nested in the cavity, wherein the cooling apparatus is in thermal contact with the die. In some embodiments, a microelectronic assembly may include a circuit board having a surface including a cavity; a substrate having a first surface attached to the circuit board and a die electrically coupled to an opposing second surface; and a cooling apparatus at least partially nested in the cavity, wherein the cooling apparatus is in thermal contact with the die.

### BACKGROUND

Mobile, tablet, ultrabook, and other portable devices based on semiconductor technology are trending towards increasingly reduced dimensions, including thinner form factors. Components are typically mounted on the surfaces of a substrate as well as a circuit board, and, as such, the overall thickness of the integrated circuit (IC) package is generally determined by the z-height of the components.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, and not by way of limitation, in the figures of the accompanying drawings.

FIG. 1A is a side, cross-sectional view of an exemplary microelectronic assembly, in accordance with various embodiments.

FIG. 1B is a side, cross-sectional view of an exemplary microelectronic assembly, in accordance with various embodiments.

FIG. 2 is a side, cross-sectional view of an exemplary microelectronic assembly, in accordance with various embodiments.

FIGS. 3A and 3B are side, cross-sectional views of example assemblies used for simulations of variants A and B.

FIG. 3C is a graph showing of the simulation results of variant A for the example assemblies of FIGS. 3A and 3B.

FIG. 3D is a graph showing of the simulation results of variant B for the example assemblies of FIGS. 3A and 3B.

FIGS. 4A-4D are side, cross-sectional views of an exemplary process for manufacturing a microelectronic assembly, in accordance with various embodiments.

FIGS. 5A-5D are side, cross-sectional views of an exemplary process for manufacturing a microelectronic assembly, in accordance with various embodiments.

FIGS. 6A-6E are side, cross-sectional views of an exemplary process for manufacturing a microelectronic assembly, in accordance with various embodiments.

FIG. 7 is a flow chart of an exemplary method for fabricating a microelectronic assembly, in accordance with various embodiments.

FIG. 8 is a top view of a wafer and dies that may be included in a microelectronic assembly, in accordance with any of the embodiments disclosed herein.

FIG. 9 is a cross-sectional side view of an IC device that may be included in a microelectronic assembly, in accordance with any of the embodiments disclosed herein.

FIG. 10 is a cross-sectional side view of an IC device assembly that may include a microelectronic assembly, in accordance with any of the embodiments disclosed herein.

FIG. 11 is a block diagram of an example electrical device that may include a microelectronic assembly, in accordance with any of the embodiments disclosed herein.

### DETAILED DESCRIPTION

Disclosed herein are microelectronic assemblies, as well as related apparatuses and methods. For example, in some embodiments, a microelectronic assembly may include a substrate having a first surface including a cavity and an opposing second surface; a die above the cavity and electrically coupled to the second surface of the substrate; a circuit board attached to the substrate; and a cooling apparatus at least partially nested in the cavity, wherein the cooling apparatus is in thermal contact with the circuit board and with the die. In some embodiments, a microelectronic assembly may include a circuit board having a surface including a cavity; a substrate having a first surface attached to the circuit board and a die electrically coupled to an opposing second surface; and a cooling apparatus at least partially nested in the cavity, wherein the cooling apparatus is in thermal contact with the die.

Communicating large numbers of signals between two or more dies in a multi-die IC package is challenging due to the increasingly small size of such dies, thermal constraints, and power delivery constraints, among others. A substrate may be used to mechanically support and electrically connect an electrical component, such as a die. A substrate may be single-sided, where components are attached on a top or bottom surface, or double-sided, where components are attached on both the top and bottom surfaces. Some conventional IC packages may include two or more active dies (i.e., two or more semiconductor devices, such as processors, controllers, logic devices, and memory devices) attached to the top and bottom surfaces of a substrate. In some conventional IC packages, two or more dies are stacked, one on top of the other on the surface of the substrate. The package may include interconnections to provide power to the semiconductor dies within the package, as well as to enable transfer of data to and from the dies. Without the stacking of dies, data interconnections between active dies (i.e., in different packages) typically require long interlinks through conductive layers of a package substrate or a circuit board, such as a motherboard. These long interconnect distances increase inductance and may reduce signal performance. However, stacking of dies, attaching dies on both surfaces of the substrate, and attaching the substrate to a circuit board may increase the overall z-height of a package and may increase thermal and/or mechanical stress on the dies.

To address the increased thermal stress on the dies, some conventional IC devices may include a cooling apparatus, such as a heat pipe, a heat spreader, a heat sink, a heat slug, or a cold plate, in order to transport heat generated by the electronic component during operation away from the electronic component. A “cooling apparatus” also may be referred to herein as a “heat transfer structure.” Typically, a cooling apparatus is in thermal contact with a heat-generating electronic component, such as a die, on an IC package and transfers heat via thermal conduction. A cooling apparatus may be attached to a back side of an IC device, to a surface of a substrate, and/or to a surface of a circuit board, which may increase overall surface area and z-height of an IC package. As IC devices become smaller, the power density increases. A smaller and more efficient IC device cooling apparatus that reduces or minimizes the heat path between the heat-generating IC device and the cooling apparatus may be desirable. The exemplary IC packages disclosed herein provide for minimized overall z-height. By incorporating cavities for cool apparatus and die attach in the substrate and/or the circuit board, the overall combined thickness or z-height of the IC package, as well as the heat path, may be minimized. Various ones of the embodiments disclosed herein may help achieve reliable attachment of multiple dies at a lower cost, with improved power efficiency, with higher bandwidth, and/or with greater design flexibility, relative to conventional approaches. Further, various ones of the microelectronic assemblies disclosed herein may exhibit better power delivery and signal speed while reducing the size of the package relative to conventional approaches. The microelectronic assemblies disclosed herein may be particularly advantageous for small and low-profile, compute-intensive applications in computers, tablets, industrial robots, and consumer electronics (e.g., wearable devices).

In the following detailed description, reference is made to the accompanying drawings that form a part hereof, wherein like numerals designate like parts throughout, and in which is shown, by way of illustration, embodiments that may be practiced. It is to be understood that other embodiments may be utilized and structural or logical changes may be made without departing from the scope of the present disclosure. Therefore, the following detailed description is not to be taken in a limiting sense. The accompanying drawings are not necessarily drawn to scale. Although many of the drawings illustrate rectilinear structures with flat walls and right-angle corners, this is simply for ease of illustration, and actual devices made using these techniques will exhibit rounded corners, surface roughness, and other features.

Various operations may be described as multiple discrete actions or operations in turn, in a manner that is most helpful in understanding the disclosed subject matter. However, the order of description should not be construed as to imply that these operations are necessarily order dependent. In particular, these operations may not be performed in the order of presentation. Operations described may be performed in a different order from the described embodiment. Various additional operations may be performed, and/or described operations may be omitted in additional embodiments.

For the purposes of the present disclosure, phrases “A and/or B” and “A or B” mean (A), (B), or (A and B). For the purposes of the present disclosure, the phrase “A, B, and/or C” means (A), (B), (C), (A and B), (A and C), (B and C), or (A, B and C). The term “between,” when used with reference to measurement ranges, is inclusive of the ends of the measurement ranges. As used herein, the notation “A/B/C” means (A), (B), and/or (C).

The description uses the phrases “in an embodiment” or “in embodiments,” which may each refer to one or more of the same or different embodiments. Furthermore, the terms “comprising,” “including,” “having,” and the like, as used with respect to embodiments of the present disclosure, are synonymous. As used herein, a “package” and an “IC package” are synonymous, as are a “die,” an “IC die,” “a microelectronic component,” and “an electrical component.” The terms “top” and “bottom” may be used herein to explain various features of the drawings, but these terms are simply for ease of discussion, and do not imply a desired or required orientation. As used herein, the term “insulating” means “electrically insulating,” unless otherwise specified. Throughout the specification, and in the claims, the term “coupled” means a direct or indirect connection, such as a direct electrical, mechanical, or magnetic connection between the things that are connected or an indirect connection, through one or more passive or active intermediary devices. The meaning of “a,” “an,” and “the” include plural references. The meaning of “in” includes “in” and “on.”

Unless otherwise specified the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner.

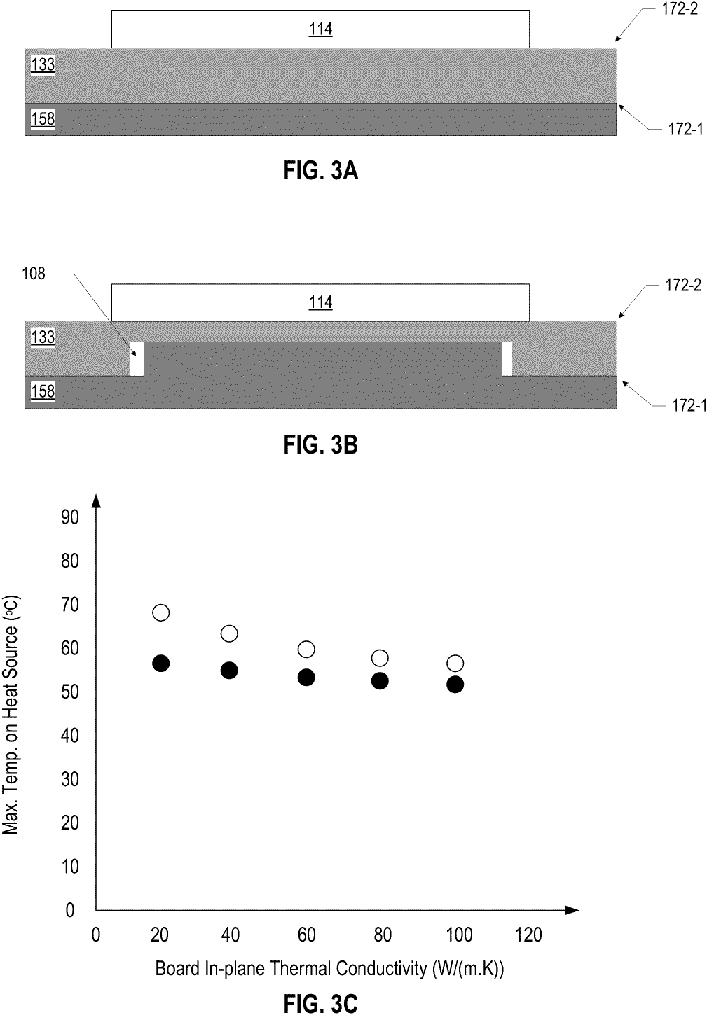

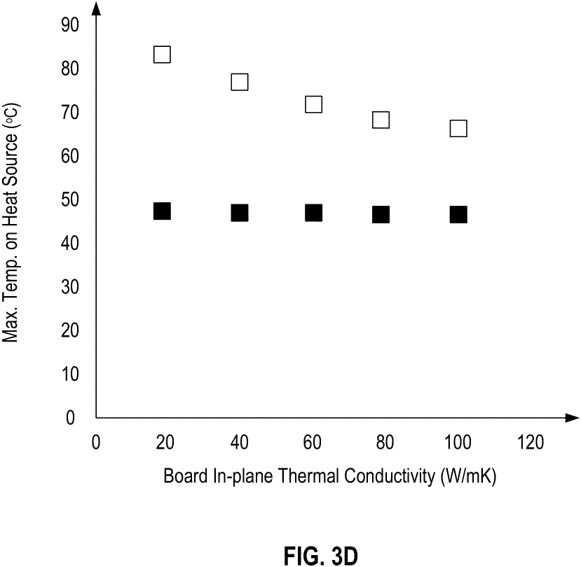

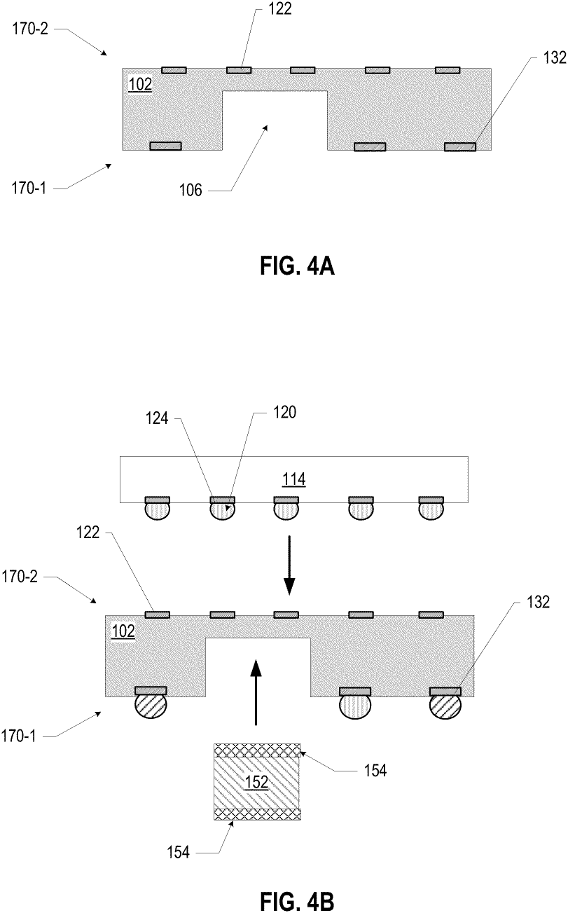

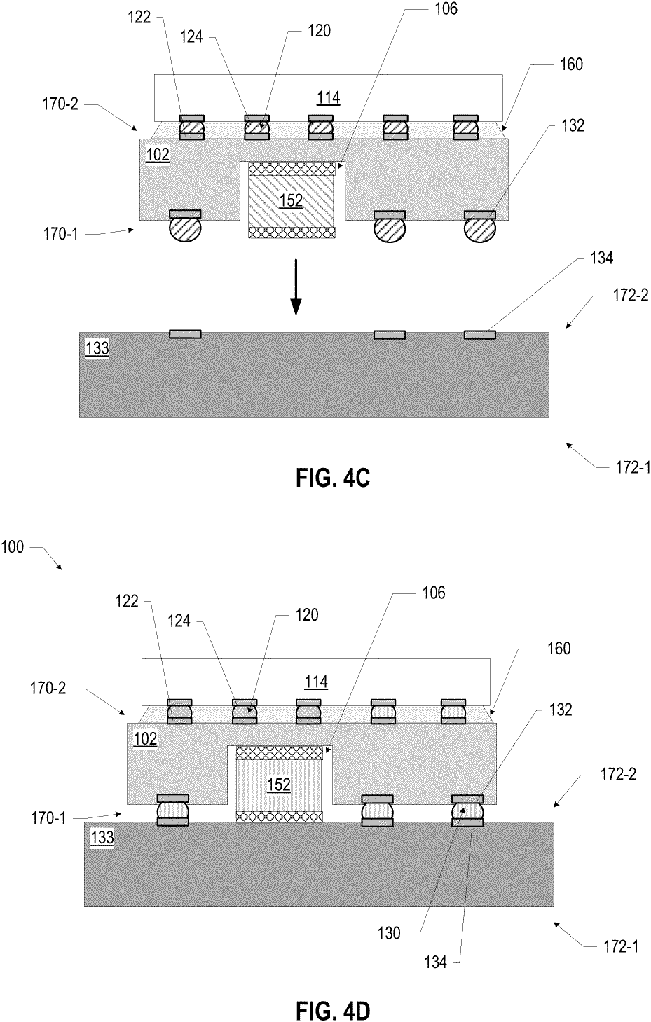

When used to describe a range of dimensions, the phrase “between X and Y” represents a range that includes X and Y. For convenience, the phrase “FIG. 3” may be used to refer to the collection of drawings of FIGS. 3A-3D, the phrase “FIG. 4” may be used to refer to the collection of drawings of FIGS. 4A-4D, etc. Although certain elements may be referred to in the singular herein, such elements may include multiple sub-elements. For example, “an insulating material” may include one or more insulating materials. As used herein, a “conductive contact” may refer to a portion of conductive material (e.g., metal) serving as an electrical interface between different components; conductive contacts may be recessed in, flush with, or extending away from a surface of a component, and may take any suitable form (e.g., a conductive pad or socket, or portion of a conductive line or via).

An “interconnect” refers to any element that provides a physical connection between two other elements. For example, an electrical interconnect provides electrical connectivity between two electrical components, facilitating communication of electrical signals between them; an optical interconnect provides optical connectivity between two optical components, facilitating communication of optical signals between them. As used herein, both electrical interconnects and optical interconnects are comprised in the term “interconnect.” The nature of the interconnect being described is to be understood herein with reference to the signal medium associated therewith. Thus, when used with reference to an electronic device, such as an IC that operates using electrical signals, the term “interconnect” describes any element formed of an electrically conductive material for providing electrical connectivity to one or more elements associated with the IC or/and between various such elements. In such cases, the term “interconnect” may refer to both conductive traces (also sometimes referred to as “metal traces,” “lines,” “metal lines,” “wires,” “metal wires,” “trenches,” or “metal trenches”) and conductive vias (also sometimes referred to as “vias” or “metal vias”). Sometimes, electrically conductive traces and vias may be referred to as “conductive traces” and “conductive vias”, respectively, to highlight the fact that these elements include electrically conductive materials such as metals. Likewise, when used with reference to a device that operates on optical signals as well, such as a photonic IC (PIC), “interconnect” may also describe any element formed of a material that is optically conductive for providing optical connectivity to one or more elements associated with the PIC. In such cases, the term “interconnect” may refer to optical waveguides (e.g., structures that guide and confine light waves), including optical fiber, optical splitters, optical combiners, optical couplers, and optical vias.

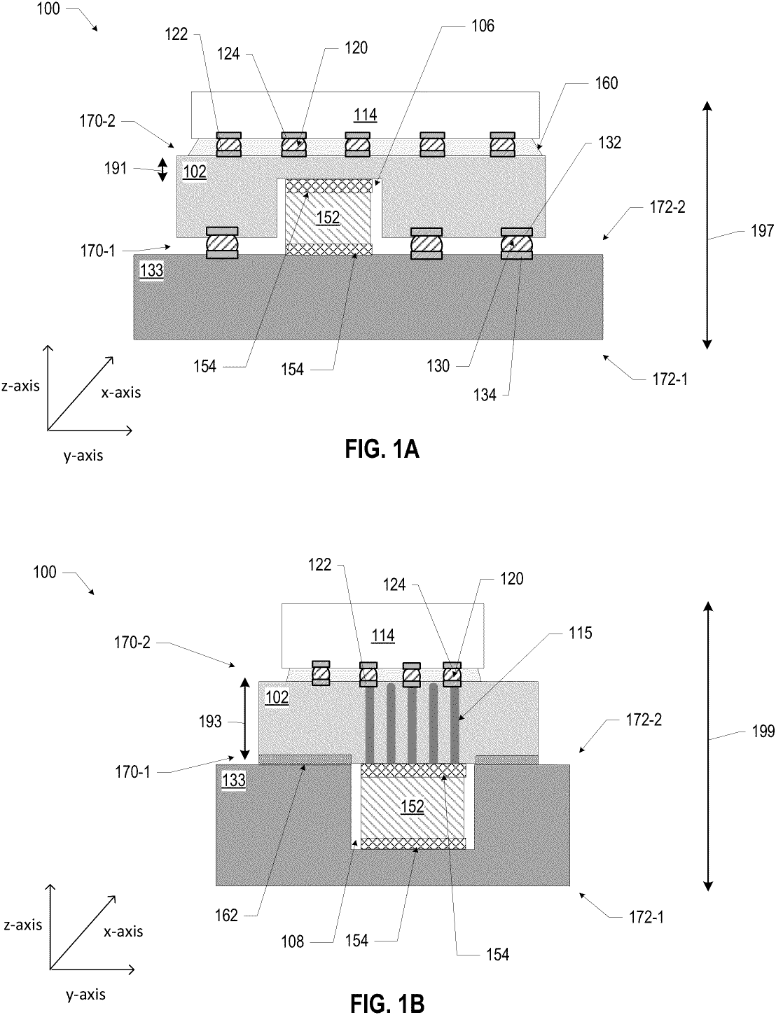

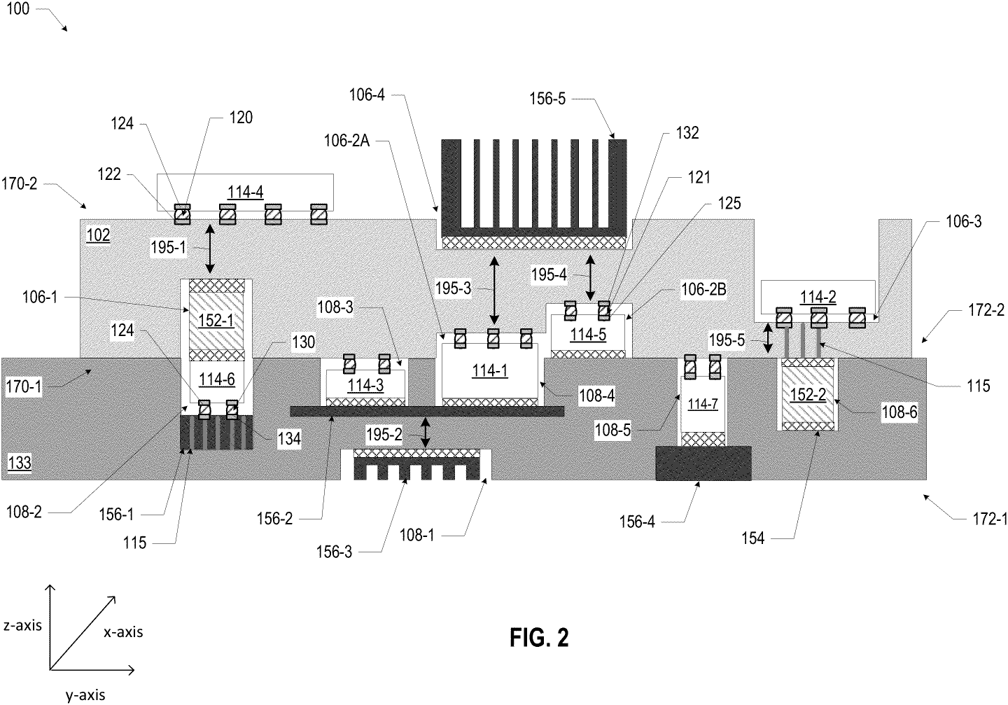

FIG. 1A is a side, cross-sectional view of an exemplary microelectronic assembly 100, in accordance with various embodiments. The microelectronic assembly 100 may include a substrate 102 having a cavity 106 with a cooling apparatus 152 disposed therein and a die 114 disposed thereon opposite the cooling apparatus 152. The cooling apparatus 152 may be attached or secured using any suitable technique, including, for example, a thermally conductive adhesive, a solder material, a thermal gel, a thermal paste, or a thermal gad pad, among others. The substrate 102 may have a bottom surface (e.g., a first surface 170-1) with a cavity 106 and an opposing top surface (e.g., a second surface 170-2). The bottom surface 170-1 of the substrate 102 may be coupled to a circuit board 133. The circuit board 133 may have a bottom surface (e.g., a first surface 172-1) and an opposing top surface (e.g., a second surface 172-2). As used herein, the term “cavity” may refer to an opening having substantially perpendicular sidewalls or may refer to an opening having stepped sidewalls such that the opening has a terraced- or tiered-contour, as described below with reference to FIG. 2. By housing the cooling apparatus 152 in the cavity 106, the heat path 191 between the die 114 and the cooling apparatus 152 as well as the overall thickness 197 (e.g., z-height) of the microelectronic assembly 100 may be reduced. For example, an overall z-height of a conventional microelectronic assembly (i.e., without cavities) may be equal to a sum of a height of the circuit board 133, a die 114, a height of the substrate 102, and a height of a cooling apparatus 152. The overall thickness 197 of the microelectronic assembly 100 is equal to a sum of the height of the circuit board 133, the height of the substrate 102, and the height of a die 114.

The die 114 may be electrically coupled to the top surface 170-2 of the substrate 102 by interconnects 120. In particular, the substrate 102 may have conductive contacts 132 on a bottom surface 170-1 and conductive contacts 122 on a top surface 170-2. The die 114 may have conductive contacts 124 on a bottom surface. The conductive contacts 124 on the bottom surface of the die 114 may be electrically coupled to the conductive contacts 122 on the top surface 170-2 of the substrate 102 by interconnects 120. The interconnects 120 may be surrounded by an underfill material 160 (e.g., the underfill material 160 may be disposed between the die 114 and the second surface 170-2 of the substrate 102). The conductive contacts 132 on the bottom surface 170-1 of the substrate 102 may be electrically coupled to the conductive contacts 134 on the top surface 172-2 of the circuit board 133 by interconnects 130. In some embodiments, one or more of the interconnects disclosed herein (e.g., interconnects 120, 130, and 121, as described below with reference to FIG. 2) may include solder bumps or balls (as illustrated in FIG. 1A); in other embodiments, the one or more interconnects 120, 130, 121 may include copper pillars, wirebonds, metal-to-metal interconnects, or any other suitable interconnects. In some embodiments, the one or more interconnects 120, 130, 121 may be surrounded by an underfill material 160. The underfill material 160 may be any suitable material. The underfill material 160 may be an insulating material, such as an appropriate epoxy material. In some embodiments, the underfill material 160 may include a capillary underfill, non-conductive film (NCF), or molded underfill. The underfill material 160 may be selected to have a CTE that may mitigate or minimize the stress between the die 114 and the substrate 102. In some embodiments, the underfill material 160 may include an epoxy flux that assists with soldering the die 114 to the substrate 102 and the substrate 102 to the circuit board 133 when forming the interconnects 120, 130, 121 respectively, and then polymerizes and encapsulates the interconnects 120, 130, 121. In some embodiments, the CTE of the underfill material 160 may have a value that is intermediate to the CTE of the substrate 102 (e.g., the CTE of the dielectric material of the substrate 102) and a CTE of the die 114 and/or the CTE of the circuit board 133. In some embodiments, the one or more interconnects 120, 130, 121 may include an anisotropic conductive material, such as an anisotropic conductive film or an anisotropic conductive paste. An anisotropic conductive material may include conductive materials dispersed in a non-conductive material.

The cooling apparatus 152 may include any suitable cooling apparatus to move heat away from the die 114 (e.g., so that the heat may be more readily dissipated from the heat-generating component). As shown in FIG. 1A, in some embodiments, the cooling apparatus 152 may span only a portion of an area (e.g., y-direction by x-direction) of the die 114, where the heat-generating portion of the die 114 is concentrated. In some embodiments, the cooling apparatus 152 may span an entire area of the die 114. In some embodiments, the cooling apparatus 152 may be greater than the area of the die 114 (e.g., may extend beyond a footprint of the die). The cooling apparatus 152 may include a heat pipe, a heat sink, a heat slug, a heat spreader, or a cold plate. In some embodiments, the cooling apparatus 152 may include a heat pipe. A heat pipe may include a conductive tube with circulating fluid therein. In such embodiments, the microelectronic assembly 100 may further include pipes or connections to a heat exchanger, a chiller, or other device for cooling the fluid (not shown). The fluid may be any suitable liquid and/or gas, such as a coolant (e.g., water, fluorochemical liquids, silicone oil, ethylene glycol water, poly-alpha-olefin, or silicate ester), or helium, argon, or nitrogen, that may be circulated, usually by a pump or a fan (not shown), to dissipate heat more efficiently from the die 114. The fluid may also include additives to prevent corrosion of the different components or to allow operation at higher/lower temperatures (e.g., additives to water to decrease its freezing point or increase its boiling point). The coolant used may depend on the coolant’s properties, including viscosity and heat capacity, circulation flow rate, boiling point, and the temperature rise during device operation. In some embodiments, the fluid may be an electronic coolant liquid or a dielectric fluid that is electrically insulating, highly thermally stable, non-toxic, chemically inert, non-corrosive with high thermal conductivity. A dielectric fluid may include a dielectric material in a liquid state. For example, the fluid may be an ultra-low-viscosity dielectric heat transfer fluid that includes synthetic hydrocarbon oils. In some embodiments, the fluid may not include sulfur. In some embodiments, the fluid may include a transformer oil, perfluoroalkanes, and purified water. The conductive structures of the cooling apparatus 152 may be formed using any suitable conductive material, including copper, silver, nickel, gold, aluminum, or other metals or alloys, or graphite, for example.

The microelectronic assembly 100 of FIG. 1A may also include a thermal interface material (TIM) 154. A TIM 154 may be disposed in the cavity 106 between the substrate 102 and the cooling apparatus 152 and/or on the top surface 172-2 of the circuit board 133 between the circuit board 133 and the cooling apparatus 152. The TIM 154 may help with transferring heat from the die 114 and hastening cooling. The TIM 154 may include a thermally conductive material (e.g., metal particles) in a polymer or other binder. The TIM 154 may be a thermal interface material paste, a thermal gel, a thermal gad pad, a thermally conductive adhesive, or a thermally conductive epoxy (which may be a fluid when applied and may harden upon curing, as known in the art). The TIM 154 may provide a path for heat generated by the die 114 to readily flow to the cooling apparatus 152, where it may be spread and/or dissipated.

The dies 114 disclosed herein may include an insulating material (e.g., a dielectric material formed in multiple layers, as known in the art) and multiple conductive pathways formed through the insulating material. In some embodiments, the insulating material of a die 114 may include a dielectric material, such as silicon dioxide, silicon nitride, oxynitride, polyimide materials, glass reinforced epoxy matrix materials, or a low-k or ultra low-k dielectric (e.g., carbon-doped dielectrics, fluorine-doped dielectrics, porous dielectrics, organic polymeric dielectrics, photo-imageable dielectrics, and/or benzocyclobutene-based polymers). In some embodiments, the insulating material of a die 114 may include a semiconductor material, such as silicon, germanium, or a III-V material (e.g., gallium nitride), and one or more additional materials. For example, an insulating material may include silicon oxide or silicon nitride. The conductive pathways in a die 114 may include conductive traces and/or conductive vias, and may connect any of the conductive contacts in the die 114 in any suitable manner (e.g., connecting multiple conductive contacts on a same surface or on different surfaces of the die 114). Example structures that may be included in the dies 114 disclosed herein are discussed below with reference to FIG. 9. The conductive pathways in the dies 114 may be bordered by liner materials, such as adhesion liners and/or barrier liners, as suitable.

The substrate 102 may include an insulating material (e.g., a dielectric material formed in multiple layers, as known in the art) and one or more conductive pathways (not shown) to route power, ground, and signals through the dielectric material (e.g., including conductive traces and/or conductive vias, as shown). In some embodiments, the insulating material of the substrate 102 may be a dielectric material, such as an organic dielectric material, a fire retardant grade 4 material (FR-4), BT resin, polyimide materials, glass reinforced epoxy matrix materials, organic dielectrics with inorganic fillers or low-k and ultra low-k dielectric (e.g., carbon-doped dielectrics, fluorine-doped dielectrics, porous dielectrics, and organic polymeric dielectrics). In particular, when the substrate 102 is formed using standard printed circuit board (PCB) processes, the substrate 102 may include FR-4, and the conductive pathways in the substrate 102 may be formed by patterned sheets of copper separated by build-up layers of the FR-4. The conductive pathways in the substrate 102 may be bordered by liner materials, such as adhesion liners and/or barrier liners, as suitable. In some embodiments, the substrate 102 may be a coreless substrate, a UTC substrate, a wafer level packaging, or any other suitable package designed to minimize z-height, as is known in the art. The substrate 102 may include conductive pathways (not shown) that allow power, ground, and other electrical signals to move between the die 114 and the substrate 102. In some embodiments, the die 114 may not be coupled to a substrate 102, but may instead be coupled to an interposer, a package substrate, or a circuit board, such as a PCB.

In some embodiments, the substrate 102 may be formed using a lithographically defined via packaging process. In some embodiments, the substrate 102 may be manufactured using standard organic package manufacturing processes, and thus the substrate 102 may take the form of an organic package. In some embodiments, the substrate 102 may be a set of redistribution layers formed on a panel carrier by laminating or spinning on a dielectric material, and creating conductive vias and lines by laser drilling or ablation and plating. In some embodiments, the substrate 102 may be formed on a removable carrier using any suitable technique, such as a redistribution layer technique. Any method known in the art for fabrication of the substrate 102 may be used, and for the sake of brevity, such methods will not be discussed in further detail herein.

In some embodiments, the substrate 102 may be a lower density medium and the die 114 may be a higher density medium or have an area with a higher density medium. As used herein, the term “lower density” and “higher density” are relative terms indicating that the conductive pathways (e.g., including conductive interconnects, conductive lines, and conductive vias) in a lower density medium are larger and/or have a greater pitch than the conductive pathways in a higher density medium. In some embodiments, a higher density medium may be manufactured using a modified semi-additive process or a semi-additive build-up process with advanced lithography (with small vertical interconnect features formed by advanced laser or lithography processes), while a lower density medium may be a PCB manufactured using a standard PCB process (e.g., a standard subtractive process using etch chemistry to remove areas of unwanted copper, and with coarse vertical interconnect features formed by a standard laser process). In other embodiments, the higher density medium may be manufactured using semiconductor fabrication process, such as a single damascene process or a dual damascene process.

The microelectronic assembly 100 may further include a circuit board 133. The conductive contacts 134 on the first surface 170-1 of the substrate 102 may be coupled to conductive contacts 132 on a surface of the circuit board 133 via interconnects 130. In some embodiments, the interconnects 130 may include solder balls (as illustrated in FIG. 1A) for a ball grid array (BGA) coupling; in other embodiments, the interconnects 130 may include solder paste contacts to provide land grid array (LGA) interconnects, or any other suitable interconnect. In some embodiments, the circuit board 133 may include one or more components disposed thereon (not shown). The circuit board 133 may include conductive pathways (not shown) that allow power, ground, and other electrical signals to move between the circuit board 133 and the substrate 102 as well as between the circuit board 133 and the die 114, as known in the art. In some embodiments, the circuit board 133 may be a PCB including multiple metal layers separated from one another by layers of dielectric material and interconnected by electrically conductive vias. In other embodiments, circuit board 133 may be a non-PCB substrate.

FIG. 1B is a side, cross-sectional view of another exemplary microelectronic assembly 100, in accordance with various embodiments. The microelectronic assembly 100 may include a substrate 102 with die 114 disposed therein coupled to a circuit board 133 having a cavity 108 housing a cooling apparatus 152. The substrate 102 may have a bottom surface (e.g., a first surface 170-1) and an opposing top surface (e.g., a second surface 170-2). The die 114 may be electrically coupled to the top surface 170-2 of the substrate 102 by interconnects 120. The die 114 may be thermally coupled to the cooling apparatus 152 by the TIM 154 and by through-substrate vias (TSVs) 115 in the substrate 102. The TSVs 115 may be formed of any suitable conductive material, such as copper, silver, nickel, gold, aluminum, other metals or alloys, or combinations of materials, for example, and may be formed using any suitable technique, including through silicon via (TSV) formation techniques. The TSVs 115 may serve as electrical connections and/or as thermal vias to dissipate heat from the die 114. By housing the cooling apparatus 152 in the cavity 108, the heat path 193 between the die 114 and the cooling apparatus 152 as well as the overall thickness (e.g., z-height) of the microelectronic assembly 100 may be reduced. For example, an overall z-height of a conventional microelectronic assembly (i.e., without cavities) may be equal to a sum of a height of the circuit board, a height of a die, a height of the substrate, and a height of a cooling apparatus 152. The overall thickness 199 of the microelectronic assembly 100 is equal to a sum of the height of the circuit board 133, the height of the substrate 102, and the height of a die 114. As shown in FIG. 1B, the substrate 102 may be coupled to the circuit board 133 by an adhesive 162, or other similar material (e.g., a thermally set adhesive dispensed in liquid, semi-liquid, or preformed formats). The substrate 102 may also be coupled to the circuit board by interconnects, such as interconnects 130, as shown in FIG. 1A, or by other electrical interconnects (not shown).

Although a single die 114 and a single cavity (e.g., cavity 106 or 108) are illustrated in FIGS. 1A and 1B, this is simply an example, and the microelectronic assembly 100 may include one or more dies 114 and one or more cavities 106, 108. The cavities 106, 108 in the microelectronic assembly 100 may be designed and configured to optimize (e.g., decrease) a heat path and an overall thickness and may depend on the number, type, and arrangement of dies 114, and on the number, type, and arrangement of substrates 102 and circuit boards 133. The dies may perform any suitable functionality, and may include processing devices, memory, communications devices, sensors, or any other computing components or circuitry. For example, the dies may include a central processing unit (CPU), a platform controller hub (PCH), a dynamic random access memory (DRAM), a graphic processing unit (GPU), and a field programmable gate array (FPGA).

Although FIGS. 1A and 1B illustrates a single IC package (e.g., a substrate 102 with die 114) disposed on the circuit board 133, this is simply for ease of illustration and multiple IC packages with multiple dies may be disposed on the circuit board 133. In some embodiments, the circuit board 133 may be a PCB (e.g., a motherboard). In some embodiments, the circuit board 133 may be an interposer, and the microelectronic assembly 100 may be a package-on-interposer structure.

Many of the elements of the microelectronic assemblies 100 of FIG. 1 are included in other ones of the accompanying figures; the discussion of these elements is not repeated when discussing these figures, and any of these elements may take any of the forms disclosed herein. Some of the elements of the microelectronic assemblies 100 of FIG. 1 are not included in other ones of the accompanying figures for simplicity, but a microelectronic assembly 100 may include these omitted elements. In some embodiments, individual ones of the microelectronic assemblies 100 disclosed herein may serve as a system-in-package (SiP) in which multiple dies 114 having different functionality are included. In such embodiments, the microelectronic assembly 100 may be referred to as an SiP.

FIG. 2 is a side, cross-sectional view of another exemplary microelectronic assembly 100, in accordance with various embodiments. The microelectronic assembly 100 may include a substrate 102 having a cavity 106-1 for housing a cooling apparatus 152-1 coupled to a circuit board 133 having a cavity 108-6 for housing a cooling apparatus 152-2. The substrate 102 may have a bottom surface (e.g., a first surface 170-1) with cavities 106-1, 106-2A, 106-2B (e.g., the cavity 106-2 including cavities 106-2A and 106-2B) and an opposing top surface (e.g., a second surface 170-2) with cavities 106-3, 106-4. The cavity 106-2 may include steps or tiers forming the internal cavities (e.g., 106-2A, 106-2B) having different depths (e.g., z-heights). The cooling apparatus 152-1 may be at least partially nested in the cavity 106-1 and may include a TIM 154. Conductive contacts 125 on a top surface of the dies 114-1, 114-3, 114-5, 114-7 may be electrically coupled to conductive contacts 132 on a bottom surface 170-1 of the substrate 102 by interconnects 121. The dies 114-3, 114-7 may be electrically coupled to the bottom surface 170-1 of the substrate 102. The dies 114-1, 114-5 may be nested in the cavity 106-2A, 106-2B, respectively, and electrically coupled to the substrate 102 by interconnects 121 (e.g., at the top surface of the cavity 106-2A, 106-2B). In particular, the die 114-1 may be at least partially nested in cavity 106-2A and die 114-5 may be partially nested in cavity 106-2B. The die 114-2 may be at least partially nested in the cavity 106-3 and electrically coupled to the top surface 170-2 of the substrate 102 by interconnects 120. The die 114-4 may be electrically coupled to the top surface 170-2 of the substrate 102 by interconnects 120. The circuit board 133 may have a bottom surface (e.g., a first surface 172-1) with a cavity 108-1 and a top surface (e.g., a second surface 172-2) with cavities 108-2, 108-3, 108-4, 108-5, 108-6. The cooling apparatus 152-2 may be at least partially nested in the cavity 108-6 and in thermal contact with the die 114-2 by the TIM 154 and by the TSVs 115. The die 114-6 may be at least partially nested in the cavity 108-2 and may be electrically coupled to the circuit board by interconnects 130 (e.g., the die 114-6 may have conductive contacts 124 on a bottom surface electrically coupled to the conductive contacts 134 in the cavity 108-2 of the circuit board 133 by interconnects 130). The dies 114-1, 114-3, and 114-7 may extend, at least partially, into a corresponding cavity 108 (e.g., the cavities 108-4, 108-3, and 108-5, respectively) in the circuit board 133. As described in FIG. 1, the substrate 102 may be coupled (not shown) to the circuit board 133 by interconnects 130 and/or by an adhesive 162, or other similar material. In some embodiments, one or more of the dies 114-1, 114-3, 114-5, 114-7 may have conductive contacts on a bottom surface that may be electrically coupled to conductive contacts on the circuit board 133 (e.g., conductive contacts on a top surface 172-2 and/or conductive contacts on the bottom surface of cavities 108).

The microelectronic assembly 100 may also include other heat transfer structures 156 in addition to the cooling apparatus 152. The heat transfer structure 156 (e.g., heat transfer structures 156-1, 156-2, 156-3, 156-4, 156-5) may be used to move heat away from one or more of the dies 114 (e.g., so that the heat may be more readily dissipated). The heat transfer structure 156 may include a heat sink, a heat slug, a heat spreader, or a cold plate. The microelectronic assembly 100 may further include a TIM 154 in thermal contact with the heat transfer structure 156 to more readily dissipate heat. The heat transfer structures 156 may include any suitable thermally conductive material (e.g., metal, appropriate ceramics, graphite, etc.), and may include any suitable features, such as a heat spreader (e.g., 156-2), a heat slug (e.g., 156-1 with TSVs 115 and 156-4), a heat sink including fins (e.g., 156-3 and 156-5), or a cold plate, etc. In some embodiments, a heat transfer structure 156 may be or may include an integrated heat spreader (IHS). The heat transfer structures 156 may have any suitable arrangement. For example, a heat transfer structure 156-5 may be at least partially nested in cavity 106-4 on the top surface 170-2 of the substrate 102 and a heat transfer structure 156-3 may be at least partially nested in cavity 108-1 on the bottom surface. In another example, the heat transfer structures 156, such as heat transfer structures 156-1, 156-2, 156-4, may be integrated at a bottom surface of a cavity 108 (e.g., cavity 108-2, 108-3, 108-4, 108-5, respectively).

The microelectronic assembly 100 of FIG. 2 may include reduced heat paths and overall thickness. By housing the cooling apparatuses 152, the dies 114, and/or the heat transfer structures 156 in the cavities 106, 108, the heat paths 195 and overall thickness (e.g., z-height) of the microelectronic assembly 100 may be reduced. For example, the cooling apparatus 152-1 housed in the cavity 106-1 may have a reduced heat path 195-1 to the die 114-4. The dies 114-1, 114-3 nested in cavities 108-4, 108-3, respectively, may have a reduced heat path 195-2 to heat transfer structure 156-3 and the thermal dissipation may be further improved by the heat transfer structure 156-2 and the TIM 154. The dies 114-1, 114-5 housed in cavities 106-2A, 106-2B may have a reduced heat paths 195-3, 195-4, respectively, to the heat transfer structure 156-5 housed in cavity 106-4. The cooling apparatus 152-2 housed in the cavity 108-6 may have a reduced heat path 195-5 to the die 114-2.

Simulations were performed using example assemblies to show improved thermal dissipation in assemblies having heat sinks in cavities for variants A and B. Parameters for variants A and B are detailed in Table 1.

TABLE 1

| | | | | |
|---|---|---|---|---|
| Variant | Board z-height | Cavity Depth | Die Footprint | Die Power |
| A | 1.6 mm (millimeters) | 0.6 mm | 20x20 mm² | 10 Watts |
| B | 1.6 mm | 1.2 mm | 20x20 mm² | 15 Watts |

FIGS. 3A and 3B are side, cross-sectional views of example assemblies used for simulations of variants A and B. FIG. 3A is a side, cross sectional view of a conventional assembly including a die 114 mounted on a top surface 172-2 of a circuit board 133 (e.g., a PCB) and a heat sink 158 mounted on a bottom surface 172-1 of the circuit board 133. As shown in FIG. 3A, the circuit board 133 does not include a cavity. FIG. 3B is a side, cross sectional view of an assembly including a die 114 mounted on a top surface 172-2 of a circuit board 133 (e.g., a PCB) and a heat sink 158 mounted on a bottom surface 172-1 of the circuit board 133, where the circuit board 133 includes a cavity 108 in a bottom surface 172-1 and the heat sink 158 extends into the cavity 108. FIGS. 3C and 3D are graphs of a maximum temperature on the heat source (e.g., die 114) in Celsius (°C) versus board (e.g., PCB) in-plane thermal conductivity in Watts per meter-Kelvin (W/mK). FIG. 3C is a graph showing of the simulation results of variant A for the example assemblies of FIG. 3A (e.g., as indicated by the white dots) and 3B (e.g., as indicated by the black dots). As shown in FIG. 3C, the assembly of FIG. 3B consistently has a lower maximum temperature as compared to the assembly of FIG. 3A due to the improved thermal dissipation with the cavity 108. FIG. 3D is a graph showing of the simulation results of variant B for the example assemblies of FIG. 3A (e.g., as indicated by the white squares) and 3B (e.g., as indicated by the black squares). As shown in FIG. 3D, the assembly of FIG. 3B consistently has a lower maximum temperature as compared to the assembly of FIG. 3A due to the improved thermal dissipation with the cavity 108.

FIGS. 4A-4D are side, cross-sectional views of an exemplary process for manufacturing the microelectronic assembly of FIG. 1A, in accordance with various embodiments. FIG. 4A illustrates a substrate 102 subsequent to forming a cavity 106 in a first surface 170-1 of the substrate 102. The substrate 102 may include a first surface 170-1 having conductive contacts 132 and an opposing second surface 170-2 having conductive contacts 122. The cavity 106 may be formed using any suitable technique. For example, the cavity 106 may be formed by laminating layers with pre-cut openings to form the cavity 106. In another example, the cavity 106 may be formed by laser cutting to a release layer and removing material of the substrate 102. The release layers may be at different depths to form stepped or tiered cavities. In another example, the cavity 106 in the substrate 102 may be formed by laser skiving, which is a selective ablation process that may remove one material with or without affecting an underlying material (e.g., selectively etching a material in a controlled order of energy delivery across the material surface for detecting a material boundary or controlling depth). In yet another example, the cavity 106 may be formed by coating an etch-resistant material, such as solder resist, on a surface of the substrate 102 to protect areas of the substrate 102 from removal and creating an opening that is formed by removing material from the exposed portions of the surface of the substrate 102. The cavity 106 may be formed using standard lithographic processes, as is known in the art. Stepped or tiered cavities may be formed by successively coating with an etch-resistant material and etching to multiple depths.

FIG. 4B illustrates an assembly subsequent to aligning a cooling apparatus 152 with the cavity 106 on the bottom surface 170-1 of the substrate 102 and aligning a die 114 for mounting on the top surface 170-2 of the substrate 102. The cooling apparatus 152 and the die 114 may be aligned and placed using any suitable process, such as pick and place tooling. A TIM 154 may be deposited on the top and bottom surfaces of the cooling apparatus 152 before placing in the cavity 106 and attaching to the substrate 102. In some embodiments, the TIM 154 may be deposited in the cavity 106 instead of on the cooling apparatus 152. Further manufacturing operations may be performed on the assemblies of FIGS. 4A and 4B, for example, surface finishing operations, among others.

FIG. 4C illustrates an assembly subsequent to electrically coupling die 114 to the substrate 102 by forming interconnects 120 and securing the cooling apparatus 152 in the cavity 106 of the substrate 102. The cooling apparatus 152 may be attached using any suitable technique, including as described above with reference to FIG. 1. In some embodiments, the interconnects 120 may include solder. In such embodiments, the assembly of FIG. 4C may be subjected to a solder reflow process during which solder components of the interconnects 120 melt and bond to mechanically and electrically couple the die 114 to the top surface 170-2 of the substrate 102. In some embodiments, an underfill material 160 may be dispensed around the interconnects 120 using any suitable process.

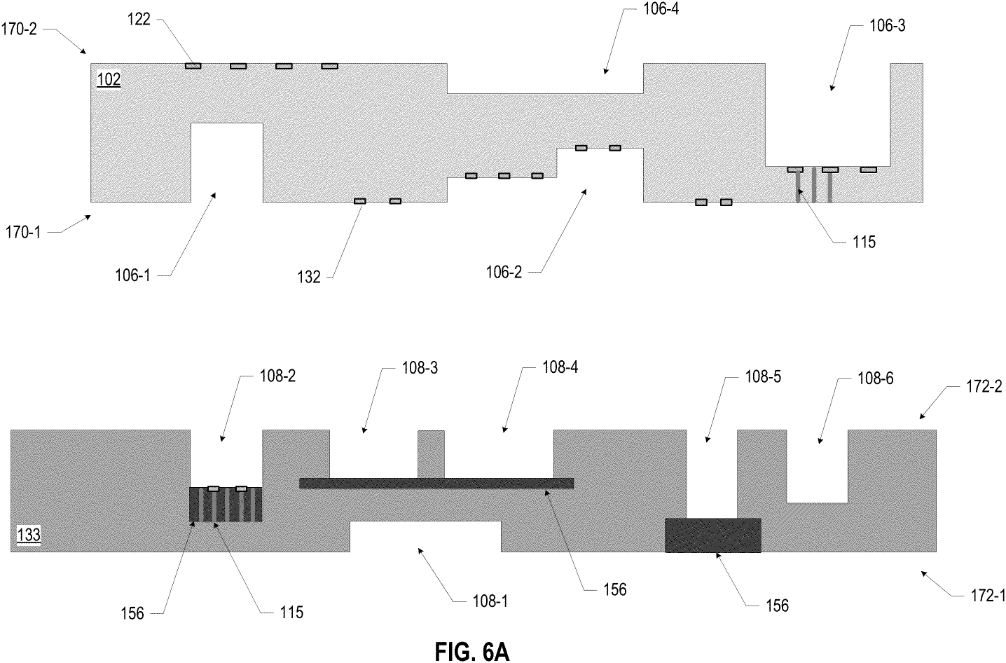

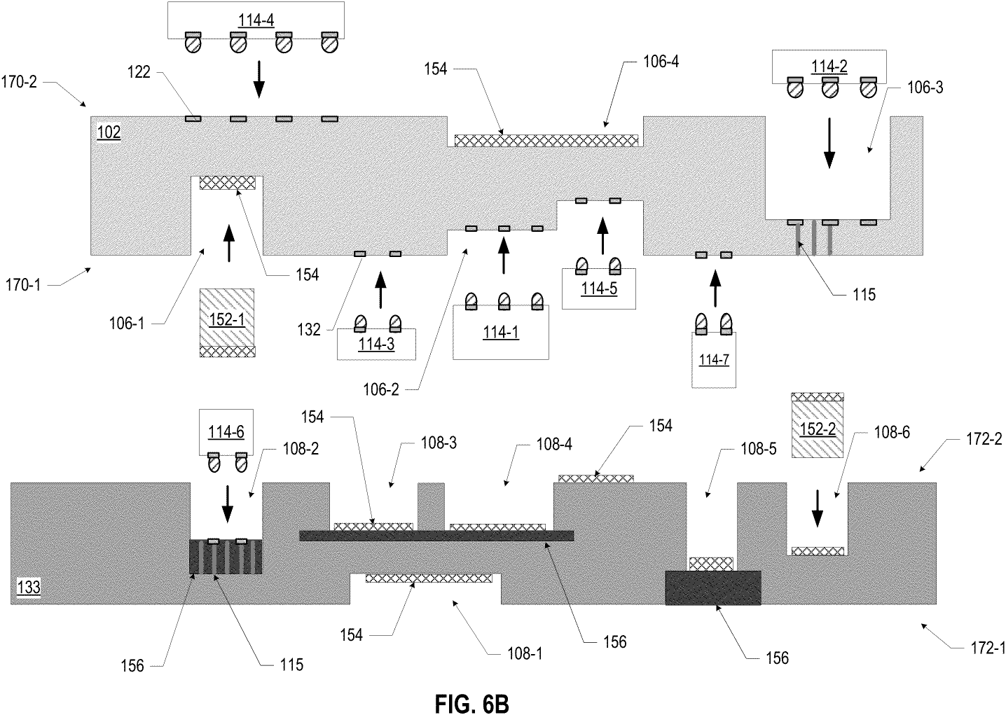

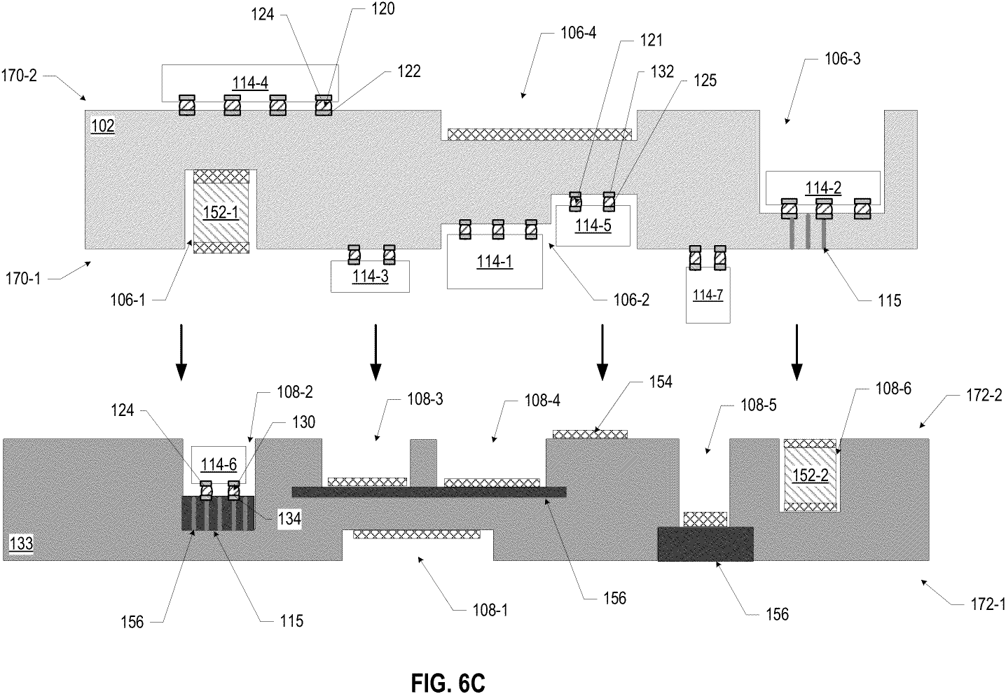

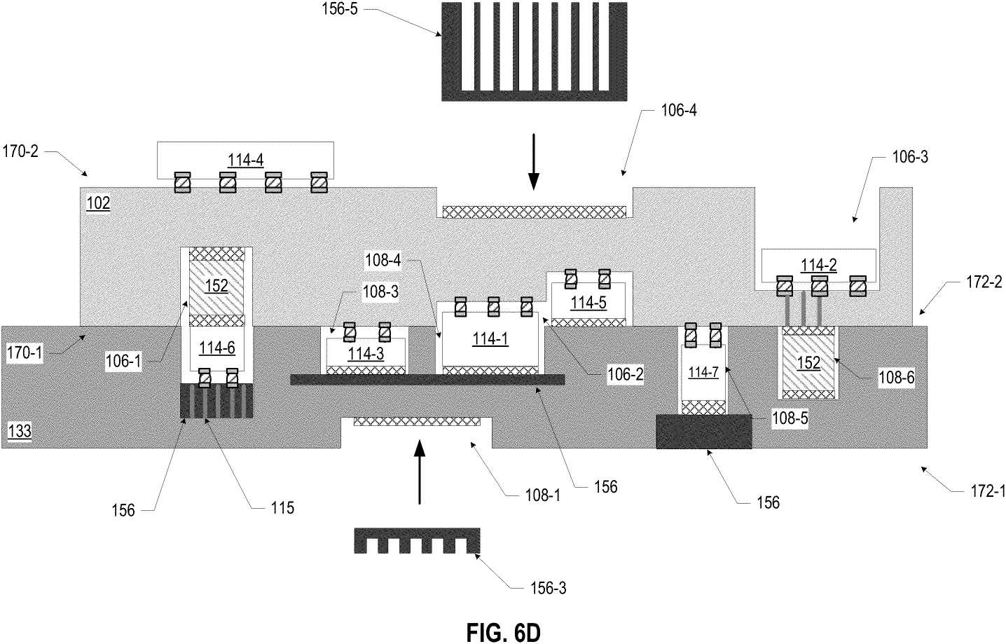

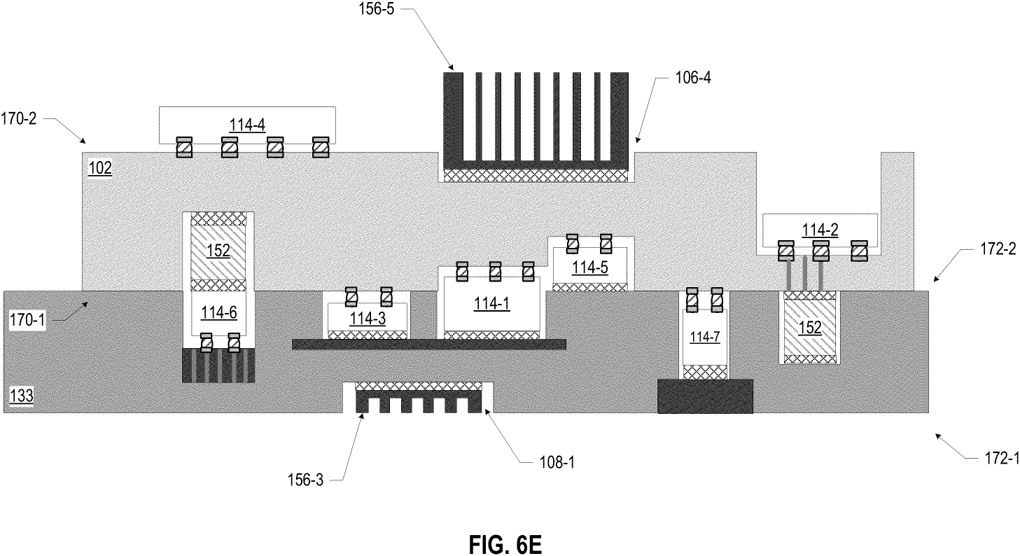

FIG. 4D illustrates an assembly subsequent to electrically coupling the substrate 102 to a circuit board 133 by forming interconnects 130. In some embodiments, the interconnects 130 may include solder. In such embodiments, the assembly of FIG. 4D may be subjected to a solder reflow process during which solder components of the interconnects 130 melt and bond to mechanically and electrically couple the bottom surface 170-1 of the substrate 102 to the top surface 172-2 of the circuit board 133. In some embodiments, an underfill material 160 (not shown) may be dispensed around the interconnects 130 using any suitable process. Further manufacturing operations may be performed on the assembly of FIG. 6D, for example, surface finishing operations, among others.

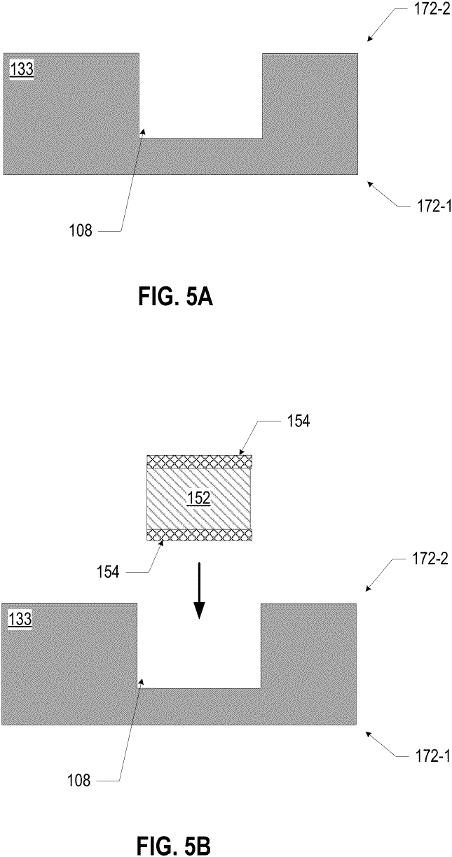

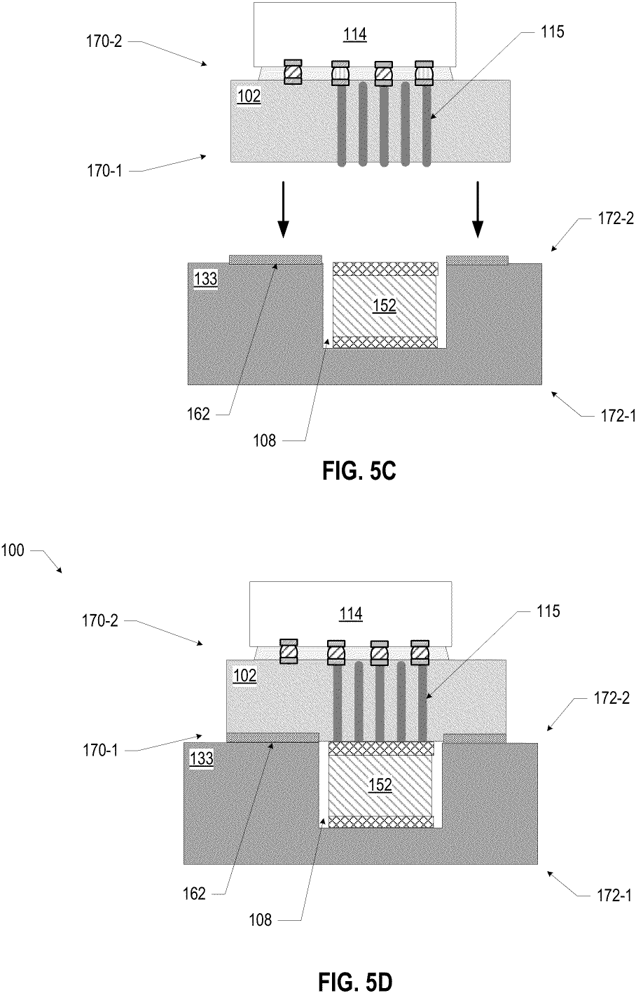

FIGS. 5A-5D are side, cross-sectional views of an exemplary process for manufacturing the microelectronic assembly of FIG. 1B, in accordance with various embodiments. FIG. 5A illustrates a circuit board 133 subsequent to forming a cavity 108 in a second surface 172-2 of the circuit board 133. The circuit board 133 may include a first surface 172-1 and an opposing second surface 172-2. The cavity 108 may be formed using any suitable technique, including the techniques described above with reference to FIG. 4A for a cavity 106.

FIG. 5B illustrates an assembly subsequent to aligning a cooling apparatus 152 with the cavity 108 on the top surface 172-1 of the circuit board 133. The cooling apparatus 152 may be aligned and placed using any suitable process, such as pick and place tooling. A TIM 154 may be deposited on the top and bottom surfaces of the cooling apparatus 152 before placing in the cavity 108 and attaching to the circuit board 133. In some embodiments, the TIM 154 may be deposited in the cavity 108 instead of on the cooling apparatus 152. Further manufacturing operations may be performed on the assemblies of FIGS. 5A and 5B, for example, surface finishing operations, among others.

FIG. 5C illustrates an assembly subsequent to securing the cooling apparatus 152 in the cavity 108 of the circuit bord 133, dispensing an adhesive material 162 on a top surface 172-2 of the circuit board 133, and aligning a substrate 102 including TSVs 115 and a die 114 electrically coupled to a top surface 170-2 by interconnects 120 with the cooling apparatus 152 in the cavity 108. The cooling apparatus 152 may be attached using any suitable technique, including as described above with reference to FIG. 1. The substrate 102 and die 114 may be aligned and placed using any suitable process, such as pick and place tooling.

FIG. 5D illustrates an assembly subsequent to attaching the substrate 102 to the circuit board 133 (e.g., by the adhesive material 162). In some embodiments, the adhesive material 162 may be a thermally set adhesive. In such embodiments, the assembly of FIG. 5D may be subjected to a thermal process for curing the adhesive. Further manufacturing operations may be performed on the assembly of FIG. 5D, for example, surface finishing operations, among others.

FIGS. 6A-6D are side, cross-sectional views of an exemplary process for manufacturing the microelectronic assembly of FIG. 2, in accordance with various embodiments. FIG. 6A illustrates a substrate 102 subsequent to forming cavities 106 (e.g., cavities 106-1, 106-2 on a first surface 170-1 of the substrate 102 and cavities 106-3, 106-4 on a second surface 170-2 of the substrate 102) and a circuit board 133 subsequent to forming cavities 108 (e.g., cavities 108-1 on a first surface 172-1 of the circuit board 133 and cavities 108-2, 108-3, 108-4, 108-5, 108-6 on a second surface 172-2 of the circuit board 133). The cavities 106, 108 may be formed using any suitable technique, such as any of the techniques described above with reference to FIG. 4A. Additional features may be formed in the substrate 102 and the circuit board 133. For example, the TSVs 115 and conductive contacts 122, 132 may be formed on the substrate 102 and the heat transfer structures 156 in the circuit board 133.

FIG. 6B illustrates an assembly subsequent to aligning a cooling apparatus 152-1 and dies 114-1, 114-3 114-5, 114-7 for mounting on the bottom surface 170-1 of the substrate 102 and dies 114-2, 114-4 for mounting on the top surface 170-2 of the substrate 102, and aligning a cooling apparatus 152-2 and die 114-6 for mounting on a top surface 172-2 of the circuit board 133. The cooling apparatuses 152 and the dies 114 may be aligned and placed using any suitable process, such as pick and place tooling. A TIM 154 may be dispensed in the cavities 106-1, 106-4, 108-1, 108-3, 108-4, 108-5, 108-6 and on the cooling apparatuses 152-1, 152-2. In some embodiments, the TIM 154 may be dispensed on both surfaces of the cooling apparatuses 152-1, 152-2 and/or on the respective surfaces of the dies 114-1, 114-3, 114-5, 114-6, 114-7. Although FIG. 6B shows components being mounted simultaneously on both surfaces, in some embodiments, components may be mounted on a surface of the substrate and then, subsequently, on an opposing second surface of the substrate (e.g., the cooling apparatus 152-1 and dies 114-1, 114-3 114-5, 114-7 may be mounted on the bottom surface 170-1 of the substrate 102 and then the dies 114-2, 114-4 may be mounted on the top surface 170-2 of the substrate 102, and vice versa).

FIG. 6C illustrates an assembly subsequent to securing the cooling apparatus 152-1 and electrically coupling the dies 114-1, 114-3, 114-5, 114-7 to the bottom surface 170-1 of the substrate 102 by forming interconnects 121 and electrically coupling the dies 114-2, 114-4 to the top surface 170-2 of the substrate 102 by forming interconnects 120, and to securing the cooling apparatus 152-2 and electrically coupling the die 114-6 to the top surface 172-2 of the circuit board 133 by interconnects 130. The cooling apparatus 152 may be attached using any suitable technique, including as described above with reference to FIG. 1. In some embodiments, the interconnects 120, 121, 130 may include solder. In such embodiments, the assembly of FIG. 6C may be subjected to a solder reflow process during which solder components of the interconnects 120, 121, 130 melt and bond to mechanically and electrically couple the dies 114 to the respective substrate 102 or circuit board 133. In some embodiments, an underfill material 160 (not shown) may be dispensed around the interconnects 120, 121, 130 and/or around all or some of the dies 114-1, 114-3, 114-5, 114-6, 114-7 (e.g., in the cavities 106, 108 and between the bottom surface 170-1 of the substrate 102 and the top surface 172-2 of the circuit board 133) using any suitable process. Further manufacturing operations may be performed on the assemblies of FIGS. 6A, 6B, and 6C, for example, surface finishing operations, among others.

FIG. 6D illustrates an assembly subsequent aligning the substrate 102 with the circuit board 133 of FIG. 6C, coupling the substrate 102 to the circuit board 133, and aligning the heat transfer structures 156-3, 156-5 with cavities 108-1, 106-4, respectively. As described above with reference to FIG. 1, the substrate 102 may be coupled (not shown) to the circuit board 133 by interconnects 130 or by an adhesive 162, or other similar material. The heat transfer structures 156-3, 156-5 may be aligned and placed using any suitable process, such as pick and place tooling.

FIG. 6E illustrates an assembly subsequent to securing the heat transfer structures 156-3, 156-5 in the cavities 108-1, 106-4, respectively. The heat transfer structures 156 may be attached using any suitable technique, including as described above with reference to the cooling apparatus 152 of FIG. 1. Further manufacturing operations may be performed on the microelectronic assembly of FIG. 6E; for example, surface finishing operations, among others.

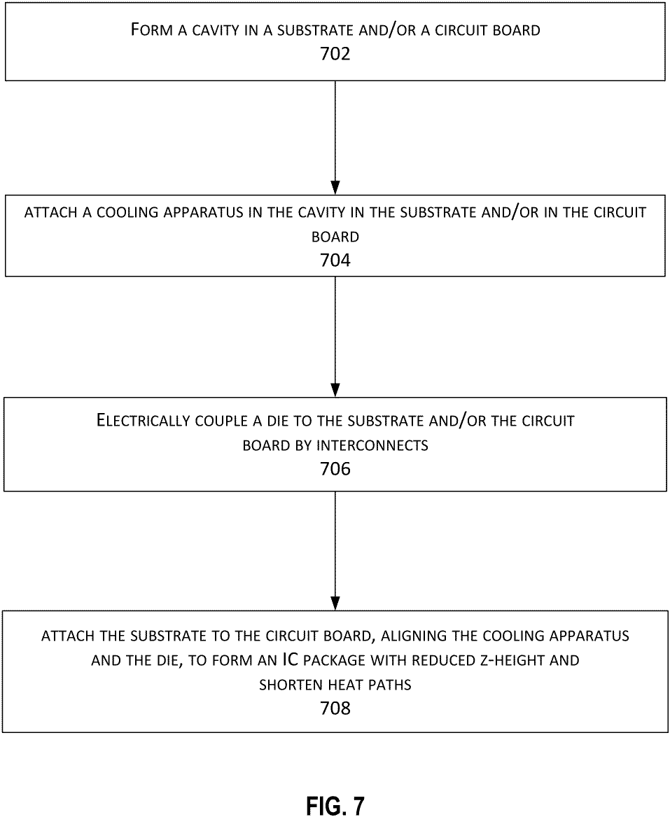

FIG. 7 is a flow chart of an exemplary method for fabricating a microelectronic assembly, in accordance with various embodiments. At 702, one or more cavities 106, 108 may be formed on a substrate 102 and/or a circuit board 133, respectively. For example, the cavity 108 may be formed to expose an embedded heat transfer structure 156 (e.g., the heat transfer structure 156-2 of FIG. 2), and/or may shorten a distance between the heat transfer structure 156 and a surface (e.g., the first and/or second surfaces 172-1, 172-2) of the circuit board 133. The one or more cavities 106, 108 may be formed using any suitable technique and may be configured based on cooling apparatus 152, die 114 arrangement, and IC package configuration. At 704, a cooling apparatus 152 or a heat transfer structure 156 may be at least partially nested in the one or more cavities 106 of the substrate 102 and/or the one or more cavities 108 of the circuit bord 133. The cooling apparatus 152 or heat transfer structure 156 may be attached to the substrate 102 and/or circuit board 133 using any suitable technique. At 706, one or more dies 114 may be at least partially nested in the cavities 106 on the substrate 102 and/or in the cavities 108 on the circuit board 133 and electrically couple to the substrate 102 by interconnects 120, 121 and the circuit board 133 by interconnects 130. At 708, the cavities 106 in the substrate 102 may be aligned with the complementary cavities 108 in the circuit board 133 and the substrate 102 may be attached to the circuit board 133, such that the heat path (e.g., heat paths 191, 193, 195 of FIGS. 1A, 1B, 2) between the cooling apparatus 152 and the die 114 is reduced and the overall z-height of the IC package is reduced. The substrate 102 may be coupled to the circuit board 133 using any suitable technique.

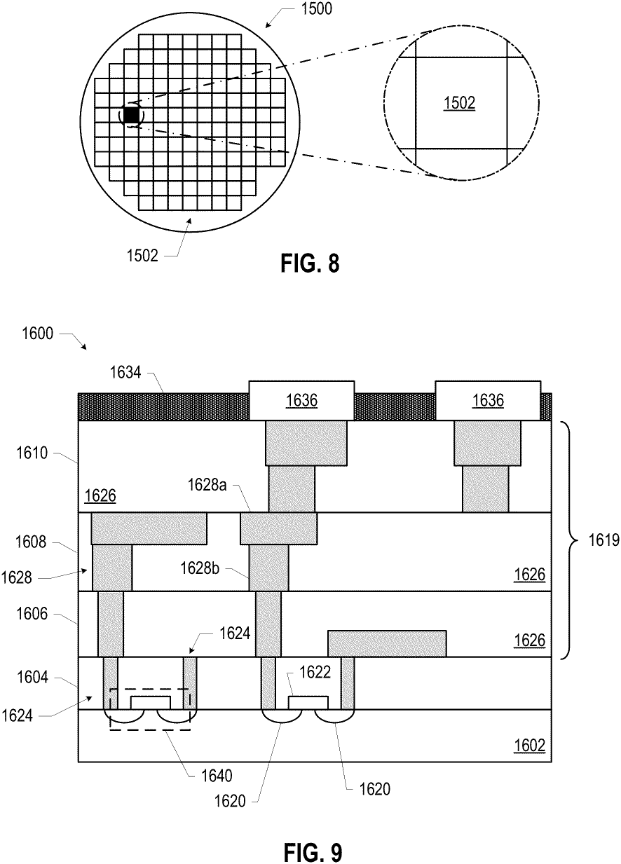

The microelectronic assemblies 100 disclosed herein may be included in any suitable electronic component. FIGS. 8-11 illustrate various examples of apparatuses that may include, or be included in, any of the microelectronic assemblies 100 disclosed herein.

FIG. 8 is a top view of a wafer 1500 and dies 1502 that may be included in any of the microelectronic assemblies 100 disclosed herein (e.g., as any suitable ones of the dies 114). The wafer 1500 may be composed of semiconductor material and may include one or more dies 1502 having IC structures formed on a surface of the wafer 1500. Each of the dies 1502 may be a repeating unit of a semiconductor product that includes any suitable IC. After the fabrication of the semiconductor product is complete, the wafer 1500 may undergo a singulation process in which the dies 1502 are separated from one another to provide discrete “chips” of the semiconductor product. The die 1502 may be any of the dies 114 disclosed herein. The die 1502 may include one or more transistors (e.g., some of the transistors 1640 of FIG. 9, discussed below), supporting circuitry to route electrical signals to the transistors, passive components (e.g., signal traces, resistors, capacitors, or inductors), and/or any other IC components. In some embodiments, the wafer 1500 or the die 1502 may include a memory device (e.g., a RAM device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Multiple ones of these devices may be combined on a single die 1502. For example, a memory array formed by multiple memory devices may be formed on a same die 1502 as a processing device (e.g., the processing device 1802 of FIG. 11) or other logic that is configured to store information in the memory devices or execute instructions stored in the memory array. In some embodiments, a die 1502 may be a central processing unit, a radio frequency chip, a power converter, or a network processor. Various ones of the microelectronic assemblies 100 disclosed herein may be manufactured using a die-to-wafer assembly technique in which some dies 114 are attached to a wafer 1500 that include others of the dies 114, and the wafer 1500 is subsequently singulated.

FIG. 9 is a cross-sectional side view of an IC device 1600 that may be included in any of the microelectronic assemblies 100 disclosed herein (e.g., in any of the dies 114). One or more of the IC devices 1600 may be included in one or more dies 1502 (FIG. 8). The IC device 1600 may be formed on a die substrate 1602 (e.g., the wafer 1500 of FIG. 8) and may be included in a die (e.g., the die 1502 of FIG. 8). The die substrate 1602 may be a semiconductor substrate composed of semiconductor material systems including, for example, n-type or p-type materials systems (or a combination of both). The die substrate 1602 may include, for example, a crystalline substrate formed using a bulk silicon or a silicon-on-insulator (SOI) substructure. In some embodiments, the die substrate 1602 may be formed using alternative materials, which may or may not be combined with silicon, that include, but are not limited to, germanium, indium antimonide, lead telluride, indium arsenide, indium phosphide, gallium arsenide, or gallium antimonide. Further materials classified as group II-VI, III-V, or IV may also be used to form the die substrate 1602. Although a few examples of materials from which the die substrate 1602 may be formed are described here, any material that may serve as a foundation for an IC device 1600 may be used. The die substrate 1602 may be part of a singulated die (e.g., the dies 1502 of FIG. 8) or a wafer (e.g., the wafer 1500 of FIG. 8).

The IC device 1600 may include one or more device layers 1604 disposed on the die substrate 1602. The device layer 1604 may include features of one or more transistors 1640 (e.g., metal oxide semiconductor field-effect transistors (MOSFETs)) formed on the die substrate 1602. The device layer 1604 may include, for example, one or more source and/or drain (S/D) regions 1620, a gate 1622 to control current flow in the transistors 1640 between the S/D regions 1620, and one or more S/D contacts 1624 to route electrical signals to/from the S/D regions 1620. The transistors 1640 may include additional features not depicted for the sake of clarity, such as device isolation regions, gate contacts, and the like. The transistors 1640 are not limited to the type and configuration depicted in FIG. 9 and may include a wide variety of other types and configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon and nanowire transistors.

Each transistor 1640 may include a gate 1622 formed of at least two layers, a gate dielectric and a gate electrode. The gate dielectric may include one layer or a stack of layers. The one or more layers may include silicon oxide, silicon dioxide, silicon carbide, and/or a high-k dielectric material. The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric to improve its quality when a high-k material is used.

The gate electrode may be formed on the gate dielectric and may include at least one p-type work function metal or n-type work function metal, depending on whether the transistor 1640 is to be a p-type metal oxide semiconductor (PMOS) or an n-type metal oxide semiconductor (NMOS) transistor. In some implementations, the gate electrode may consist of a stack of two or more metal layers, where one or more metal layers are work function metal layers and at least one metal layer is a fill metal layer. Further metal layers may be included for other purposes, such as a barrier layer. For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some embodiments, when viewed as a cross-section of the transistor 1640 along the source-channel-drain direction, the gate electrode may consist of a U-shaped structure that includes a bottom portion substantially parallel to the surface of the die substrate 1602 and two sidewall portions that are substantially perpendicular to the top surface of the die substrate 1602. In other embodiments, at least one of the metal layers that form the gate electrode may simply be a planar layer that is substantially parallel to the top surface of the die substrate 1602 and does not include sidewall portions substantially perpendicular to the top surface of the die substrate 1602. In other embodiments, the gate electrode may consist of a combination of U-shaped structures and planar, non-U-shaped structures. For example, the gate electrode may consist of one or more U-shaped metal layers formed atop one or more planar, non-U-shaped layers.

In some embodiments, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and generally include deposition and etching process steps. In some embodiments, a plurality of spacer pairs may be used; for instance, two pairs, three pairs, or four pairs of sidewall spacers may be formed on opposing sides of the gate stack.

The S/D regions 1620 may be formed within the die substrate 1602 adjacent to the gate 1622 of each transistor 1640. The S/D regions 1620 may be formed using an implantation/diffusion process or an etching/deposition process, for example. In the former process, dopants such as boron, aluminum, antimony, phosphorous, or arsenic may be ion-implanted into the die substrate 1602 to form the S/D regions 1620. An annealing process that activates the dopants and causes them to diffuse farther into the die substrate 1602 may follow the ion-implantation process. In the latter process, the die substrate 1602 may first be etched to form recesses at the locations of the S/D regions 1620. An epitaxial deposition process may then be carried out to fill the recesses with material that is used to fabricate the S/D regions 1620. In some implementations, the S/D regions 1620 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 1620 may be formed using one or more alternate semiconductor materials such as germanium or a group III-V material or alloy. In further embodiments, one or more layers of metal and/or metal alloys may be used to form the S/D regions 1620.

Electrical signals, such as power and/or input/output (I/O) signals, may be routed to and/or from the devices (e.g., transistors 1640) of the device layer 1604 through one or more interconnect layers disposed on the device layer 1604 (illustrated in FIG. 9 as interconnect layers 1606-1610). For example, electrically conductive features of the device layer 1604 (e.g., the gate 1622 and the S/D contacts 1624) may be electrically coupled with the interconnect pathways 1628 of the interconnect layers 1606-1610. The one or more interconnect layers 1606-1610 may form a metallization stack (also referred to as an “ILD stack”) 1619 of the IC device 1600.

The interconnect pathways 1628 may be arranged within the interconnect layers 1606-1610 to route electrical signals according to a wide variety of designs; in particular, the arrangement is not limited to the particular configuration of interconnect pathways 1628 depicted in FIG. 9. Although a particular number of interconnect layers 1606-1610 is depicted in FIG. 9, embodiments of the present disclosure include IC devices having more or fewer interconnect layers than depicted.

In some embodiments, the interconnect pathways 1628 may include lines 1628a and/or vias 1628b filled with an electrically conductive material such as a metal. The lines 1628a may be arranged to route electrical signals in a direction of a plane that is substantially parallel with a surface of the die substrate 1602 upon which the device layer 1604 is formed. For example, the lines 1628a may route electrical signals in a direction in and out of the page from the perspective of FIG. 9. The vias 1628b may be arranged to route electrical signals in a direction of a plane that is substantially perpendicular to the surface of the die substrate 1602 upon which the device layer 1604 is formed. In some embodiments, the vias 1628b may electrically couple lines 1628a of different interconnect layers 1606-1610 together.

The interconnect layers 1606-1610 may include a dielectric material 1626 disposed between the interconnect pathways 1628, as shown in FIG. 9. In some embodiments, the dielectric material 1626 disposed between the interconnect pathways 1628 in different ones of the interconnect layers 1606-1610 may have different compositions; in other embodiments, the composition of the dielectric material 1626 between different interconnect layers 1606-1610 may be the same.

A first interconnect layer 1606 (referred to as Metal 1 or “M1”) may be formed directly on the device layer 1604. In some embodiments, the first interconnect layer 1606 may include lines 1628a and/or vias 1628b, as shown. The lines 1628a of the first interconnect layer 1606 may be coupled with contacts (e.g., the S/D contacts 1624) of the device layer 1604.

A second interconnect layer 1608 (referred to as Metal 2 or “M2”) may be formed directly on the first interconnect layer 1606. In some embodiments, the second interconnect layer 1608 may include vias 1628b to couple the lines 1628a of the second interconnect layer 1608 with the lines 1628a of the first interconnect layer 1606. Although the lines 1628a and the vias 1628b are structurally delineated with a line within each interconnect layer (e.g., within the second interconnect layer 1608) for the sake of clarity, the lines 1628a and the vias 1628b may be structurally and/or materially contiguous (e.g., simultaneously filled during a dual damascene process) in some embodiments.

A third interconnect layer 1610 (referred to as Metal 3 or “M3”) (and additional interconnect layers, as desired) may be formed in succession on the second interconnect layer 1608 according to similar techniques and configurations described in connection with the second interconnect layer 1608 or the first interconnect layer 1606. In some embodiments, the interconnect layers that are “higher up” in the metallization stack 1619 in the IC device 1600 (i.e., farther away from the device layer 1604) may be thicker.

The IC device 1600 may include a solder resist material 1634 (e.g., polyimide or similar material) and one or more conductive contacts 1636 formed on the interconnect layers 1606-1610. In FIG. 9, the conductive contacts 1636 are illustrated as taking the form of bond pads. The conductive contacts 1636 may be electrically coupled with the interconnect pathways 1628 and configured to route the electrical signals of the transistor(s) 1640 to other external devices. For example, solder bonds may be formed on the one or more conductive contacts 1636 to mechanically and/or electrically couple a chip including the IC device 1600 with another component (e.g., a circuit board). The IC device 1600 may include additional or alternate structures to route the electrical signals from the interconnect layers 1606-1610; for example, the conductive contacts 1636 may include other analogous features (e.g., posts) that route the electrical signals to external components.

In some embodiments in which the IC device 1600 is a double-sided die (e.g., like the die 114-1), the IC device 1600 may include another metallization stack (not shown) on the opposite side of the device layer(s) 1604. This metallization stack may include multiple interconnect layers as discussed above with reference to the interconnect layers 1606-1610, to provide conductive pathways (e.g., including conductive lines and vias) between the device layer(s) 1604 and additional conductive contacts (not shown) on the opposite side of the IC device 1600 from the conductive contacts 1636.

In other embodiments in which the IC device 1600 is a double-sided die (e.g., like the die 114-1), the IC device 1600 may include one or more TSVs through the die substrate 1602; these TSVs may make contact with the device layer(s) 1604, and may provide conductive pathways between the device layer(s) 1604 and additional conductive contacts (not shown) on the opposite side of the IC device 1600 from the conductive contacts 1636.

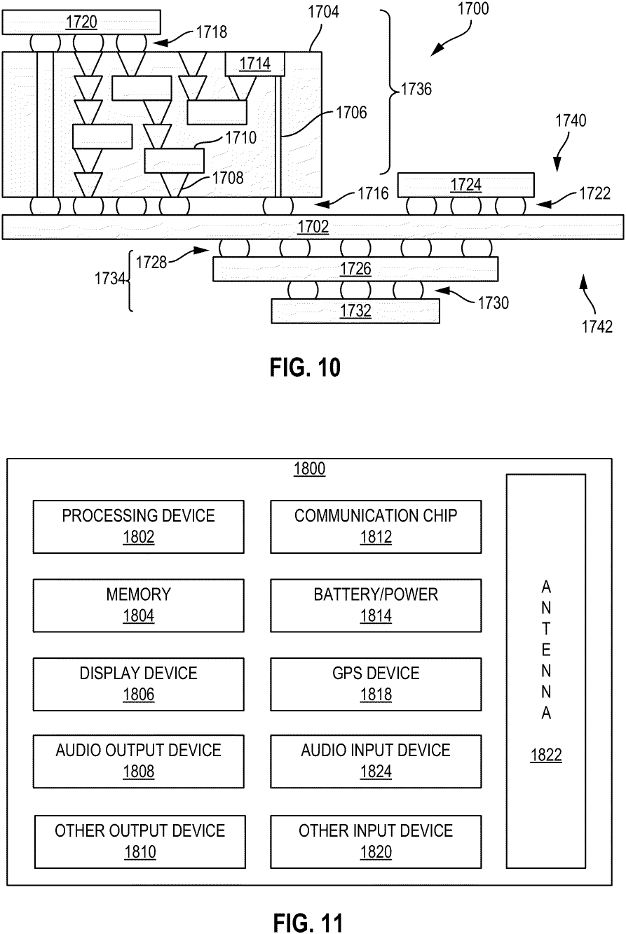

FIG. 10 is a cross-sectional side view of an IC device assembly 1700 that may include any of the microelectronic assemblies 100 disclosed herein. In some embodiments, the IC device assembly 1700 may be a microelectronic assembly 100. The IC device assembly 1700 includes a number of components disposed on a circuit board 1702 (which may be, e.g., a motherboard). The IC device assembly 1700 includes components disposed on a first face 1740 of the circuit board 1702 and an opposing second face 1742 of the circuit board 1702; generally, components may be disposed on one or both faces 1740 and 1742. Any of the IC packages discussed below with reference to the IC device assembly 1700 may take the form of any suitable ones of the embodiments of the microelectronic assemblies 100 disclosed herein.

In some embodiments, the circuit board 1702 may be a PCB including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 1702. In other embodiments, the circuit board 1702 may be a non-PCB substrate. In some embodiments the circuit board 1702 may be, for example, a circuit board.

The IC device assembly 1700 illustrated in FIG. 10 includes a package-on-interposer structure 1736 coupled to the first face 1740 of the circuit board 1702 by coupling components 1716. The coupling components 1716 may electrically and mechanically couple the package-on-interposer structure 1736 to the circuit board 1702, and may include solder balls (as shown in FIG. 10), male and female portions of a socket, an adhesive, an underfill material, and/or any other suitable electrical and/or mechanical coupling structure.

The package-on-interposer structure 1736 may include an IC package 1720 coupled to an interposer 1704 by coupling components 1718. The coupling components 1718 may take any suitable form for the application, such as the forms discussed above with reference to the coupling components 1716. Although a single IC package 1720 is shown in FIG. 10, multiple IC packages may be coupled to the interposer 1704; indeed, additional interposers may be coupled to the interposer 1704. The interposer 1704 may provide an intervening substrate used to bridge the circuit board 1702 and the IC package 1720. The IC package 1720 may be or include, for example, a die (the die 1502 of FIG. 8), an IC device (e.g., the IC device 1600 of FIG. 9), or any other suitable component. Generally, the interposer 1704 may spread a connection to a wider pitch or reroute a connection to a different connection. For example, the interposer 1704 may couple the IC package 1720 (e.g., a die) to a set of ball grid array (BGA) conductive contacts of the coupling components 1716 for coupling to the circuit board 1702. In the embodiment illustrated in FIG. 10, the IC package 1720 and the circuit board 1702 are attached to opposing sides of the interposer 1704; in other embodiments, the IC package 1720 and the circuit board 1702 may be attached to a same side of the interposer 1704. In some embodiments, three or more components may be interconnected by way of the interposer 1704.

In some embodiments, the interposer 1704 may be formed as a PCB, including multiple metal layers separated from one another by layers of dielectric material and interconnected by electrically conductive vias. In some embodiments, the interposer 1704 may be formed of an epoxy resin, a fiberglass-reinforced epoxy resin, an epoxy resin with inorganic fillers, a ceramic material, or a polymer material such as polyimide. In some embodiments, the interposer 1704 may be formed of alternate rigid or flexible materials that may include the same materials described above for use in a semiconductor substrate, such as silicon, germanium, and other group III-V and group IV materials. The interposer 1704 may include metal interconnects 1708 and vias 1710, including but not limited to TSVs 1706. The interposer 1704 may further include embedded devices 1714, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 1704. The package-on-interposer structure 1736 may take the form of any of the package-on-interposer structures known in the art.

The IC device assembly 1700 may include an IC package 1724 coupled to the first face 1740 of the circuit board 1702 by coupling components 1722. The coupling components 1722 may take the form of any of the embodiments discussed above with reference to the coupling components 1716, and the IC package 1724 may take the form of any of the embodiments discussed above with reference to the IC package 1720.

The IC device assembly 1700 illustrated in FIG. 10 includes a package-on-package structure 1734 coupled to the second face 1742 of the circuit board 1702 by coupling components 1728. The package-on-package structure 1734 may include an IC package 1726 and an IC package 1732 coupled together by coupling components 1730 such that the IC package 1726 is disposed between the circuit board 1702 and the IC package 1732. The coupling components 1728 and 1730 may take the form of any of the embodiments of the coupling components 1716 discussed above, and the IC packages 1726 and 1732 may take the form of any of the embodiments of the IC package 1720 discussed above. The package-on-package structure 1734 may be configured in accordance with any of the package-on-package structures known in the art.

FIG. 11 is a block diagram of an example electrical device 1800 that may include one or more of the microelectronic assemblies 100 disclosed herein. For example, any suitable ones of the components of the electrical device 1800 may include one or more of the IC device assemblies 1700, IC devices 1600, or dies 1502 disclosed herein, and may be arranged in any of the microelectronic assemblies 100 disclosed herein. A number of components are illustrated in FIG. 11 as included in the electrical device 1800, but any one or more of these components may be omitted or duplicated, as suitable for the application. In some embodiments, some or all of the components included in the electrical device 1800 may be attached to one or more motherboards. In some embodiments, some or all of these components are fabricated onto a single system-on-a-chip (SoC) die.

Additionally, in various embodiments, the electrical device 1800 may not include one or more of the components illustrated in FIG. 11, but the electrical device 1800 may include interface circuitry for coupling to the one or more components. For example, the electrical device 1800 may not include a display device 1806, but may include display device interface circuitry (e.g., a connector and driver circuitry) to which a display device 1806 may be coupled. In another set of examples, the electrical device 1800 may not include an audio input device 1824 or an audio output device 1808, but may include audio input or output device interface circuitry (e.g., connectors and supporting circuitry) to which an audio input device 1824 or audio output device 1808 may be coupled.

The electrical device 1800 may include a processing device 1802 (e.g., one or more processing devices). As used herein, the term “processing device” or “processor” may refer to any device or portion of a device that processes electronic data from registers and/or memory to transform that electronic data into other electronic data that may be stored in registers and/or memory. The processing device 1802 may include one or more digital signal processors (DSPs), application-specific ICs (ASICs), central processing units (CPUs), graphics processing units (GPUs), cryptoprocessors (specialized processors that execute cryptographic algorithms within hardware), server processors, or any other suitable processing devices. The electrical device 1800 may include a memory 1804, which may itself include one or more memory devices such as volatile memory (e.g., dynamic RAM (DRAM)), nonvolatile memory (e.g., read-only memory (ROM)), flash memory, solid state memory, and/or a hard drive. In some embodiments, the memory 1804 may include memory that shares a die with the processing device 1802. This memory may be used as cache memory and may include embedded dynamic RAM (eDRAM) or spin transfer torque magnetic RAM (STT-MRAM).

In some embodiments, the electrical device 1800 may include a communication chip 1812 (e.g., one or more communication chips). For example, the communication chip 1812 may be configured for managing wireless communications for the transfer of data to and from the electrical device 1800. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

The communication chip 1812 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 1812 may operate in accordance with a Global System for Mobile Communication (GSM), General Packet Radio Service (GPRS), Universal Mobile Telecommunications System (UMLS), High Speed Packet Access (HSPA), Evolved HSPA (E-HSPA), or LTE network. The communication chip 1812 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 1812 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 1812 may operate in accordance with other wireless protocols in other embodiments. The electrical device 1800 may include an antenna 1822 to facilitate wireless communications and/or to receive other wireless communications (such as AM or FM radio transmissions).

In some embodiments, the communication chip 1812 may manage wired communications, such as electrical, optical, or any other suitable communication protocols (e.g., the Ethernet). As noted above, the communication chip 1812 may include multiple communication chips. For instance, a first communication chip 1812 may be dedicated to shorter-range wireless communications such as Wi-Fi or Bluetooth, and a second communication chip 1812 may be dedicated to longer-range wireless communications such as global positioning system (GPS), EDGE, GPRS, CDMA, WiMAX, LTE, EV-DO, or others. In some embodiments, a first communication chip 1812 may be dedicated to wireless communications, and a second communication chip 1812 may be dedicated to wired communications.

The electrical device 1800 may include battery/power circuitry 1814. The battery/power circuitry 1814 may include one or more energy storage devices (e.g., batteries or capacitors) and/or circuitry for coupling components of the electrical device 1800 to an energy source separate from the electrical device 1800 (e.g., AC line power).

The electrical device 1800 may include a display device 1806 (or corresponding interface circuitry, as discussed above). The display device 1806 may include any visual indicators, such as a heads-up display, a computer monitor, a projector, a touchscreen display, a liquid crystal display (LCD), a light-emitting diode display, or a flat panel display.

The electrical device 1800 may include an audio output device 1808 (or corresponding interface circuitry, as discussed above). The audio output device 1808 may include any device that generates an audible indicator, such as speakers, headsets, or earbuds.

The electrical device 1800 may include an audio input device 1824 (or corresponding interface circuitry, as discussed above). The audio input device 1824 may include any device that generates a signal representative of a sound, such as microphones, microphone arrays, or digital instruments (e.g., instruments having a musical instrument digital interface (MIDI) output).

The electrical device 1800 may include a GPS device 1818 (or corresponding interface circuitry, as discussed above). The GPS device 1818 may be in communication with a satellite-based system and may receive a location of the electrical device 1800, as known in the art.

The electrical device 1800 may include an other output device 1810 (or corresponding interface circuitry, as discussed above). Examples of the other output device 1810 may include an audio codec, a video codec, a printer, a wired or wireless transmitter for providing information to other devices, or an additional storage device.

The electrical device 1800 may include an other input device 1820 (or corresponding interface circuitry, as discussed above). Examples of the other input device 1820 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The electrical device 1800 may have any desired form factor, such as a computing device or a mobile computing device (e.g., a hand-held, portable or mobile electrical device, such as a cell phone, a smart phone, a mobile internet device, a music player, a tablet computer, a laptop computer, a netbook computer, an ultrabook computer, a personal digital assistant (PDA), an ultra mobile personal computer, etc.), a desktop electrical device, a server, or other networked computing component, a printer, a scanner, a monitor, a set-top box, an entertainment control unit, a vehicle control unit, a digital camera, a digital video recorder, or a wearable computing device. In some embodiments, the electrical device 1800 may be any other electronic device that processes data.

The following examples pertain to further embodiments. The various features of the different embodiments may be variously combined with some features included and others excluded to suit a variety of different applications.

Example 1 is a microelectronic assembly, including a substrate having a first surface including a cavity and an opposing second surface; a die above the cavity and electrically coupled to the second surface of the substrate; a circuit board having a surface attached to the first surface of the substrate; and a cooling apparatus at least partially nested in the cavity, wherein the cooling apparatus is in thermal contact with the die through the substrate.

Example 2 may include the subject matter of Example 1, and may further specify that the cooling apparatus is a heat pipe, a heat sink, a heat slug, a heat spreader, or a cold plate.

Example 3 may include the subject matter of Examples 1 or 2, and may further specify that the substrate is attached to the circuit board by an adhesive material.

Example 4 may include the subject matter of Examples 1 or 2, and may further specify that the substrate is attached to the circuit board by interconnects that electrically couple the substrate to the circuit board.

Example 5 may include the subject matter of any of Examples 1-4, and may further specify that the die is a first die, the cavity is a first cavity, and the microelectronic assembly may further include a second cavity in the first surface of the substrate; a second die at least partially nested in the second cavity and electrically coupled to the substrate; and a third cavity in the surface of the circuit board, wherein the second die extends at least partially into the third cavity in the circuit board.

Example 6 may include the subject matter of Example 5, and may further include a heat transfer structure at a bottom surface of the third cavity in the circuit board, wherein the second die is in thermal contact with the heat transfer structure.

Example 7 may include the subject matter of Example 5, and may further include a fourth cavity in the second surface of the substrate, above the second die; and a heat transfer structure at least partially nested in the fourth cavity and in thermal contact with the second die.

Example 8A may include the subject matter of any of Examples 1-7, and may further include a thermal interface material (TIM) between the cooling apparatus and the substrate.

Example 8B may include the subject matter of any of Examples 1-7, and may further include a thermal interface material (TIM) at a top surface of the cavity between the cooling apparatus and the circuit board.

Example 8C may include the subject matter of Example 6, and may further include a thermal interface material (TIM) between the second die and the heat transfer structure.

Example 8D may include the subject matter of Example 7, and may further include a thermal interface material (TIM) at a bottom surface of the fourth cavity between the heat transfer structure and the substrate.

Example 9 may include the subject matter of any of Examples 1-8, and may further specify that the substrate is a package substrate.

Example 10 may include the subject matter of any of Examples 1-9, and may further specify that the circuit board is a printed circuit board.

Example 11 is a microelectronic assembly, including a circuit board having a surface, the surface including a cavity; a substrate having a first surface and an opposing second surface, wherein the substrate includes through-substrate vias (TSVs), and wherein the first surface of the substrate is attached to the surface of the circuit board; a die electrically coupled to the second surface of the substrate; and a cooling apparatus at least partially nested in the cavity, wherein the cooling apparatus is in thermal contact with the die through the TSVs in the substrate.

Example 12 may include the subject matter of Example 11, and may further specify that the cooling apparatus is a heat pipe, a heat sink, a heat slug, a heat spreader, or a cold plate.

Example 13 may include the subject matter of Example 12, and may further specify that the cooling apparatus is a heat pipe and the heat pipe includes a fluid.

Example 14 may include the subject matter of any of Examples 11-13, and may further specify that the die is a first die, the cavity is a first cavity, and the microelectronic assembly may further include a second cavity in the surface of the circuit board; and a second die electrically coupled to the first surface of the substrate, wherein the second die extends at least partially into the second cavity in the circuit board.

Example 15 may include the subject matter of Example 14, and may further include a heat transfer structure at a bottom surface of the second cavity in the circuit board, wherein the second die is in thermal contact with the heat transfer structure.

Example 16 may include the subject matter of Example 15, and may further include a thermal interface material (TIM) between the second die and the heat transfer structure.

Example 17 may include the subject matter of Example 15, and may further specify that the heat transfer structure includes a heat sink, a heat slug, a heat spreader, or a cold plate.

Example 18 may include the subject matter of Example 14, and may further include an underfill material around the second die and between the first surface of the substrate and the surface of the circuit board.

Example 19 may include the subject matter of any of Examples 11-18, and may further specify that the substrate is attached to the circuit board by an adhesive material.

Example 20 may include the subject matter of any of Examples 11-18, and may further specify that the substrate is attached to the circuit board by interconnects that electrically couple the substrate to the circuit board.

Example 21 is a computing device, including a substrate having a first surface and an opposing second surface, wherein the first surface of the substrate including a first cavity and the second surface of the substrate including a second cavity; a first die above the first cavity and electrically coupled to the second surface of the substrate; a second die at least partially nested in the second cavity and electrically coupled to the substrate; a circuit board having a surface, the surface including a third cavity, wherein the circuit board is attached to the first surface of the substrate, and wherein the third cavity is below the second die; a first cooling apparatus at least partially nested in the first cavity in the substrate, wherein the first cooling apparatus is in thermal contact with the first die; and a second cooling apparatus at least partially nested in the third cavity, wherein the second cooling apparatus is in thermal contact with the second die.

Example 22 may include the subject matter of Example 21, and may further include through-substrate vias (TSVs) in the substrate extending from the first surface of the substrate to a bottom surface of the second cavity, and wherein the second cooling apparatus is further in thermal contact with the second die through the TSVs in the substrate.

Example 23 may include the subject matter of Examples 21 or 22, and may further specify that the substrate is attached to a bottom surface of the third cavity in the circuit board by an adhesive material.

Example 24 may include the subject matter of Examples 21 or 22, and may further specify that the substrate is attached to a bottom surface of the third cavity in the circuit board by interconnects that electrically couple the substrate to the circuit board.

Example 25 may include the subject matter of any of Examples 21-24, and may further specify that the first die or the second die is selected from the group consisting of a central processing unit, a platform controller hub, a memory die, a field programmable gate array silicon die, and graphic processing unit.

Example 26 may include the subject matter of any of Examples 21-24, and may further specify that the first die or the second die includes a memory device.

Example 27 may include the subject matter of any of Examples 21-26, and may further specify that the computing device is included in a server device.

Example 28 may include the subject matter of any of Examples 21-26, and may further specify that the computing device is included in a portable computing device.

Example 29 may include the subject matter of any of Examples 21-26, and may further specify that the computing device is included in a wearable computing device.

Example 30 is a method of manufacturing a microelectronic assembly, including forming a cavity in a first surface of a substrate, wherein the substrate includes the first surface and an opposing second surface; electrically coupling a die to the second surface of the substrate, wherein the die is above the cavity; at least partially nesting a cooling apparatus in the cavity, wherein the cooling apparatus is in thermal contact with the die through the substrate; attaching the first surface of the substrate to a surface of a circuit board.

Example 31 may include the subject matter of Example 30, and may further specify that the substrate is attached to the circuit board by an adhesive material.

Example 32 may include the subject matter of Example 30, and may further specify that the substrate is attached to the circuit board by interconnects that electrically couple the substrate to the circuit board.

Example 33 may include the subject matter of any of Examples 30-32, and may further specify that the die is a first die, the cavity is a first cavity, and the method may further include forming a second cavity in the first surface of the substrate; at least partially nesting a second die in the second cavity and electrically coupling the second die to the substrate; and forming a third cavity in the surface of the circuit board; and wherein attaching the first surface of the substrate to the surface of the circuit board includes aligning the substrate and the circuit board with the second die extending at least partially into the third cavity in the circuit board.

Example 34 may include the subject matter of Example 33, and may further include forming a heat transfer structure at a bottom surface of the third cavity in the circuit board and in thermal contact with the second die.

Example 35 may include the subject matter of any of Examples 30-34, and may further specify that the cooling apparatus is a heat pipe including a fluid.

Example 36 is a method of manufacturing a microelectronic assembly, including forming a cavity in a surface of a circuit board; at least partially nesting a cooling apparatus in the cavity; electrically coupling a die to a second surface of a substrate, wherein the substrate includes a first surface and the opposing second surface, and wherein the substrate includes through-substrate vias (TSVs) and the die is coupled to the TSVs; and attaching the first surface of the substrate to the surface of the circuit board with the cooling apparatus below the die, and wherein the cooling apparatus is in thermal contact with the die through the TSVs in the substrate.

Example 37 may include the subject matter of Example 36, and may further specify that the cooling apparatus is a heat pipe including a fluid.

Example 38 may include the subject matter of Examples 36 or 37, and may further specify that the die is a first die, the cavity is a first cavity, and the microelectronic assembly may further include forming a second cavity in the surface of the circuit board; and electrically coupling a second die to the first surface of the substrate, wherein the second die extends at least partially into the second cavity in the circuit board.

Example 39 may include the subject matter of Example 38, and may further include forming a heat transfer structure at a bottom surface of the second cavity in the circuit board, wherein the second die is in thermal contact with the heat transfer structure.

Example 40 may include the subject matter of Example 39, and may further specify that the heat transfer structure includes a heat sink, a heat slug, a heat spreader, or a cold plate.

1. A microelectronic assembly, comprising:
a substrate having a first surface including a cavity and an opposing second surface;
a die above the cavity and electrically coupled to the second surface of the substrate;
a circuit board having a surface attached to the first surface of the substrate; and
a cooling apparatus at least partially nested in the cavity, wherein the cooling apparatus is in thermal contact with the die through the substrate.

2. The microelectronic assembly of claim 1, wherein the cooling apparatus is a heat pipe, a heat sink, a heat slug, a heat spreader, or a cold plate.

3. The microelectronic assembly of claim 1, wherein the substrate is attached to the circuit board by an adhesive material.

4. The microelectronic assembly of claim 1, wherein the substrate is attached to the circuit board by interconnects that electrically couple the substrate to the circuit board.

5. The microelectronic assembly of claim 1, wherein the die is a first die, wherein the cavity is a first cavity, and the microelectronic assembly, further comprising:
a second cavity in the first surface of the substrate;
a second die at least partially nested in the second cavity and electrically coupled to the substrate; and
a third cavity in the surface of the circuit board, wherein the second die extends at least partially into the third cavity in the circuit board.

6. The microelectronic assembly of claim 5, further comprising:
a heat transfer structure at a bottom surface of the third cavity in the circuit board, wherein the second die is in thermal contact with the heat transfer structure.

7. The microelectronic assembly of claim 5, further comprising:
a fourth cavity in the second surface of the substrate, wherein the fourth cavity is above the second die; and
a heat transfer structure at least partially nested in the fourth cavity and in thermal contact with the second die.

8. The microelectronic assembly of claim 1, further comprising:
a thermal interface material (TIM) between the cooling apparatus and the substrate.

9. A microelectronic assembly, comprising:
a circuit board having a surface, the surface including a cavity;
a substrate having a first surface and an opposing second surface, wherein the substrate includes through-substrate vias (TSVs), and wherein the first surface of the substrate is attached to the surface of the circuit board;
a die electrically coupled to the second surface of the substrate; and
a cooling apparatus at least partially nested in the cavity, wherein the cooling apparatus is in thermal contact with the die through the TSVs in the substrate.

10. The microelectronic assembly of claim 9, wherein the cooling apparatus is a heat pipe, a heat sink, a heat slug, a heat spreader, or a cold plate.

11. The microelectronic assembly of claim 10, wherein the cooling apparatus is a heat pipe and the heat pipe includes a fluid.

12. The microelectronic assembly of claim 9, wherein the die is a first die, wherein the cavity is a first cavity, and the microelectronic assembly, further comprising:
a second cavity in the surface of the circuit board; and
a second die electrically coupled to the first surface of the substrate, wherein the second die extends at least partially into the second cavity in the circuit board.

13. The microelectronic assembly of claim 12, further comprising:
a heat transfer structure at a bottom surface of the second cavity in the circuit board, wherein the second die is in thermal contact with the heat transfer structure.

14. The microelectronic assembly of claim 13, wherein the heat transfer structure includes a heat sink, a heat slug, a heat spreader, or a cold plate.

15. The microelectronic assembly of claim 12, further comprising:
an underfill material around the second die and between the first surface of the substrate and the surface of the circuit board.

16. A computing device, comprising:
a substrate having a first surface and an opposing second surface, wherein the first surface of the substrate including a first cavity and the second surface of the substrate including a second cavity;
a first die above the first cavity and electrically coupled to the second surface of the substrate;
a second die at least partially nested in the second cavity and electrically coupled to the substrate;
a circuit board having a surface, the surface including a third cavity, wherein the circuit board is attached to the first surface of the substrate, and wherein the third cavity is below the second die;
a first cooling apparatus at least partially nested in the first cavity in the substrate, wherein the first cooling apparatus is in thermal contact with the first die; and
a second cooling apparatus at least partially nested in the third cavity, wherein the second cooling apparatus is in thermal contact with the second die.

17. The computing device of claim 16, further comprising:
through-substrate vias (TSVs) in the substrate extending from the first surface of the substrate to a bottom surface of the second cavity, and wherein the second cooling apparatus is further in thermal contact with the second die through the TSVs in the substrate.

18. The computing device of claim 16, wherein the first cooling apparatus is a heat pipe, a heat sink, a heat slug, a heat spreader, or a cold plate.

19. The computing device of claim 16, wherein the first die or the second die is selected from the group consisting of a central processing unit, a platform controller hub, a memory die, a field programmable gate array silicon die, and graphic processing unit.

20. The computing device of claim 16, wherein the computing device is included in a server device.
